(19) United States
(12) Patent Application Publication
(10) Pub. No.: US 2026/0255567 A1
(43) Pub. Date: Aug. 27, 2026

(54) SEMICONDUCTOR DEVICE

(71) Applicant: Samsung Electronics Co., Ltd., Suwon-si (KR)

(72) Inventors: Deukho Yeon, Suwon-si (KR); Mingyu Kim, Suwon-si (KR); Sungil Park, Suwon-si (KR); Jae Hyun Park, Suwon-si (KR)

(73) Assignee: Samsung Electronics Co., Ltd., Suwon-si (KR)

(21) Appl. No.: 19/343,289

(22) Filed: Sep. 29, 2025

(30) Foreign Application Priority Data
Feb. 25, 2025 (KR) 10-2025-0024291

(51) Int. Cl. H10B 10/00

(52) U.S. Cl. CPC H10B 10/125

(57) ABSTRACT

A semiconductor device includes a plurality of upper sheet patterns spaced apart from one another in a first direction on a first separation insulating layer, a first gate electrode surrounding the plurality of upper sheet patterns and extending in a second direction, a second gate electrode spaced apart from the first gate electrode in the second direction, a lower source/drain pattern disposed on one side of the first separation insulating layer, a first upper source/drain pattern disposed on one side of the plurality of upper sheet patterns, a first through contact and penetrating at least a portion of the first upper source/drain pattern and at least a portion of the lower source/drain pattern, and a first lower gate contact disposed on a lower surface of the second gate electrode and extending in the second direction, wherein the first lower gate contact is electrically connected to the first through contact.

### CROSS-REFERENCE TO RELATED APPLICATIONS

This present application claims priority to and the benefit under 35 U.S.C. § 119(a)-(d) of Korean Patent Application No. 10-2025-0024291, filed on Feb. 25, 2025, in the Korean Intellectual Property Office, the entire disclosure of which is incorporated herein by reference.

### FIELD

The present disclosure relates to a semiconductor device.

### BACKGROUND

Semiconductor elements are core components used to control or amplify electrical signals in electronic devices, and various types of semiconductor elements may be manufactured. For example, memory elements may primarily be used to store and retrieve data, and non-memory elements may be used to control or amplify electrical signals. Semiconductor elements serve as key components of electronic devices, playing an important role in various fields such as computers, communication equipment, and consumer electronics.

With industrial development, demands for higher performance and more functions of electronic devices are increasing. Accordingly, high-performance characteristics of semiconductor elements are essential, and the degree of integration of semiconductor elements is increasing to meet these demands. Various methods for forming semiconductor elements having superior performance and improved integration are being researched.

### SUMMARY

In order to solve one or more problems (e.g., the problems described above and/or other problems not explicitly described herein), the present disclosure is directed to providing a semiconductor device with improved integration.

In order to solve one or more problems (e.g., the problems described above and/or other problems not explicitly described herein), the present disclosure is directed to providing a method of manufacturing the semiconductor device with improved integration.

According to some embodiments of the present disclosure, a semiconductor device may include a plurality of upper sheet patterns spaced apart from one another in a first direction on a first separation insulating layer, a first gate electrode surrounding the plurality of upper sheet patterns and extending in a second direction intersecting the first direction, a second gate electrode spaced apart from the first gate electrode in the second direction and extending in the second direction, a lower source/drain pattern disposed on one side of the first separation insulating layer, a first upper source/drain pattern disposed on one side of the plurality of upper sheet patterns and spaced apart from the lower source/drain pattern in the first direction, a first through contact extending in the first direction and penetrating at least a portion of the first upper source/drain pattern and at least a portion of the lower source/drain pattern, and a first lower gate contact disposed on a lower surface of the second gate electrode and extending in the second direction, wherein the first lower gate contact is electrically connected to the first through contact.

According to some embodiments of the present disclosure, a semiconductor device may include a plurality of upper sheet patterns spaced apart from one another in a first direction on a separation insulating layer, a first gate electrode surrounding the plurality of upper sheet patterns and extending in a second direction intersecting the first direction, a first upper source/drain pattern and a second upper source/drain pattern disposed on both sides of the plurality of upper sheet patterns, a first lower source/drain pattern disposed on one side of the separation insulating layer, a through contact extending in the first direction and penetrating at least a portion of each of the second upper source/drain pattern and the first lower source/drain pattern, a third upper source/drain pattern spaced apart from the second upper source/drain pattern in a third direction intersecting each of the first direction and the second direction, a second lower source/drain pattern spaced apart from the first lower source/drain pattern in the third direction, a second gate electrode disposed between the first lower source/drain pattern and the second lower source/drain pattern and between the second upper source/drain pattern and the third upper source/drain pattern, a third gate electrode spaced apart from the first gate electrode in the second direction, a first upper line wiring electrically connected to the third upper source/drain pattern, a first lower line wiring electrically connected to the second lower source/drain pattern, and a lower gate contact disposed on a lower surface of the third gate electrode, extending in the second direction, and electrically connected to the through contact.

According to some embodiments of the present disclosure, a semiconductor device may include a plurality of upper sheet patterns spaced apart from one another in a first direction on a separation insulating layer, a first gate electrode surrounding the plurality of upper sheet patterns and extending in a second direction intersecting the first direction, a first upper source/drain pattern and a second upper source/drain pattern respectively disposed on both sides of the plurality of upper sheet patterns, a first lower source/drain pattern disposed on one side of the separation insulating layer, a through contact extending in the first direction and penetrating each of the second upper source/drain pattern and the first lower source/drain pattern, a third upper source/drain pattern spaced apart from the second upper source/drain pattern in a third direction intersecting each of the first direction and the second direction, a second lower source/drain pattern spaced apart from the first lower source/drain pattern in the third direction, a second gate electrode disposed between the first lower source/drain pattern and the second lower source/drain pattern and between the second upper source/drain pattern and the third upper source/drain pattern, a third gate electrode spaced apart from the first gate electrode in the second direction, a lower gate contact disposed on a lower surface of the third gate electrode, electrically connected to the through contact, and extending in the second direction, a lower via disposed on a lower surface of the through contact, a first lower line wiring disposed on a lower surface of the lower via and connecting the lower via and the lower gate contact, a second lower line wiring electrically connected to the second lower source/drain pattern, a bit line electrically connected to the first upper source/drain pattern, a first upper line wiring electrically connected to the third upper source/drain pattern, and a second upper line wiring electrically connected to the first gate electrode, wherein the first lower line wiring and the second lower line wiring are disposed at a same vertical level, and wherein the bit line, the first upper line wiring, and the second upper line wiring are disposed at a same vertical level.

According to some embodiments of the present disclosure, a semiconductor device manufacturing method may include forming a plurality of first to fourth lower sheet patterns and a plurality of first to fourth upper sheet patterns on a substrate, forming first to sixth lower source/drain patterns and first to sixth upper source/drain patterns on the substrate, forming first to fourth gate electrodes on the substrate, forming a first through electrode that penetrates at least a portion of a second upper source/drain pattern and at least a portion of a second lower source/drain pattern and a second through electrode that penetrates at least a portion of a fifth upper source/drain pattern and at least a portion of a fifth lower source/drain pattern, removing a portion of a first gate electrode to form a first separation insulating layer and removing a portion of a fourth gate electrode to form a second separation insulating layer, and forming a first lower gate contact connected to a third gate electrode and a second lower gate contact connected to a second gate electrode.

According to some embodiments, the first lower gate contact may include a first portion extending in a first direction and a second portion extending in a second direction intersecting the first direction, and the second portion may contact a lower surface of the first through electrode.

According to some embodiments, the first lower gate contact may include a first portion extending in a first direction and a second portion extending in a second direction intersecting the first direction, and the second portion may contact a lower surface of a second lower source/drain pattern.

According to some embodiments, the first through electrode may penetrate upper and lower surfaces of the second upper source/drain pattern and upper and lower surfaces of the second lower source/drain pattern.

According to some embodiments, the first through electrode may penetrate upper and lower surfaces of the second upper source/drain pattern, and one end of the first through electrode may be disposed inside the second lower source/drain pattern.

According to some embodiments, the first separation insulating layer may overlap, in a direction parallel to an upper surface of the substrate, the plurality of first lower sheet patterns, and the second separation insulating layer may overlap, in a direction parallel to an upper surface of the substrate, the plurality of second lower sheet patterns.

According to some embodiments, the first lower gate contact and the second lower gate contact may be disposed at a same vertical level.

According to some embodiments, forming the first separation insulating layer and the second separation insulating layer may include removing the substrate to expose lower surfaces of the first gate electrode and the fourth gate electrode, removing a portion of the first gate electrode and a plurality of third lower sheet patterns to form the first separation insulating layer, and removing a portion of the fourth gate electrode and a plurality of fourth lower sheet patterns to form the second separation insulating layer.

According to some embodiments, the plurality of first upper sheet patterns may overlap the first separation insulating layer in a direction perpendicular to the upper surface of the substrate, and the plurality of fourth upper sheet patterns may overlap the second separation insulating layer in a direction substantially perpendicular to the upper surface of the substrate.

According to some embodiments, the semiconductor device manufacturing method may further include forming a first lower via disposed on a lower surface of the first through electrode and a second lower via disposed on a lower surface of the second through electrode, and forming a first lower line wiring that connects the first lower gate contact and the first lower via and a second lower line wiring that connects the second lower gate contact and the second lower via.

According to some embodiments of the present disclosure, by forming a lower gate contact, a lower line wiring, a lower via, and a through contact, the degree of integration of the semiconductor device may be improved.

According to some embodiments of the present disclosure, by separating wirings that configure the semiconductor device into upper line wiring and lower line wiring, the degree of integration of the semiconductor device may be improved.

### BRIEF DESCRIPTION OF THE DRAWINGS

The above and other embodiments and features of the present disclosure will become more apparent by describing in detail example embodiments thereof with reference to the attached drawings, in which:

FIG. 1 is a circuit diagram illustrating the semiconductor device according to some embodiments of the present disclosure;

FIGS. 2 and 3 are exemplary plan views illustrating a semiconductor device according to some embodiments of the present disclosure;

FIG. 4 is a cross-sectional view taken along line A-A′ of FIGS. 2 and 3;

FIG. 5 is a cross-sectional view taken along line B-B′ of FIGS. 2 and 3;

FIG. 6 is a cross-sectional view taken along line C-C′ of FIGS. 2 and 3;

FIG. 7 is a cross-sectional view taken along line D-D′ of FIGS. 2 and 3;

FIG. 8 is an exemplary plan view illustrating a semiconductor device according to some embodiments of the present disclosure;

FIG. 9 is a cross-sectional view taken along line A-A′ of FIG. 8;

FIG. 10 is a cross-sectional view taken along line B-B′ of FIG. 8;

FIG. 11 is a cross-sectional view taken along line C-C′ of FIG. 8;

FIG. 12 is a cross-sectional view taken along line D-D′ of FIG. 8;

FIGS. 13 and 14 are diagrams illustrating a semiconductor device according to some embodiments of the present disclosure;

FIGS. 15 and 16 are diagrams illustrating a semiconductor device according to some embodiments of the present disclosure;

FIGS. 17 and 18 are exemplary plan views illustrating a semiconductor device according to some embodiments of the present disclosure;

FIG. 19 is a cross-sectional view taken along line C-C′ of FIGS. 17 and 18;

FIG. 20 is a cross-sectional view taken along line D-D′ of FIGS. 17 and 18;

FIGS. 21 and 22 are diagrams illustrating a semiconductor device according to some embodiments of the present disclosure;

FIGS. 23-34 are diagrams illustrating a method of manufacturing a semiconductor device according to some embodiments of the present disclosure.

### DETAILED DESCRIPTION

In the present disclosure, the terms “upper,” “lower,” “upper surface,” and “lower surface” are used for convenience of explanation and are not limiting. The terms “upper,” “lower,” “upper surface,” and “lower surface” are described based on what is shown in the drawings, and the terms for referring to the upper-lower relationship may change when the drawings are rotated vertically.

In the present disclosure, although first, second, etc. are used to describe various elements or components, these elements or components are not limited by these terms. These terms are used merely to distinguish one element or component from another. Of course, a first element or component mentioned below may be a second element or component within the technical scope of the present disclosure.

According to some embodiments of the present disclosure, the semiconductor device may include a MOSFET (metal-oxide-semiconductor field effect transistor). More specifically, the semiconductor device may include a 3D multi-stacked semiconductor device called a GAA (gate-all-around) transistor or MBCFET (multi-bridge channel FET).

Hereinafter, the semiconductor device and its manufacturing method according to some embodiments of the present disclosure will be described in detail with reference to the drawings.

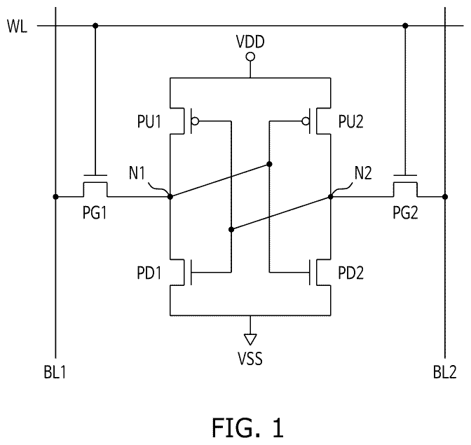

FIG. 1 is a circuit diagram illustrating the semiconductor device according to some embodiments of the present disclosure.

Referring to FIG. 1, according to some embodiments, the semiconductor device may include at least one cell. The cell may be, for example, an SRAM (static random access memory) cell. The cell may include a word line WL, a first bit line BL1, a second bit line BL2, and a plurality of transistors. FIG. 1 may be a circuit diagram illustrating a cell of the semiconductor device.

According to some embodiments, the semiconductor device may include a first pass transistor PG1, a second pass transistor PG2, a first pull-up transistor PU1, a second pull-up transistor PU2, a first pull-down transistor PD1, and a second pull-down transistor PD2.

The first pull-up transistor PU1 and the second pull-up transistor PU2 may be P-type MOSFETs. The first pass transistor PG1, the second pass transistor PG2, the first pull-down transistor PD1, and the second pull-down transistor PD2 may be N-type MOSFETs. The semiconductor device may include six transistors configured as four NMOS transistors and two PMOS transistors. However, the present disclosure is not limited thereto.

The switching electrodes (e.g., gate electrodes) of the first pass transistor PG1 and the second pass transistor PG2 may be connected to the word line WL. A source pattern of the first pass transistor PG1 may be connected to the first bit line BL1. A source pattern of the second pass transistor PG2 may be connected to the second bit line BL2. A positive voltage (for example, VDD) may be applied to a source pattern of the first pull-up transistor PU1. A positive voltage (for example, VDD) may be applied to a source pattern of the second pull-up transistor PU2. A negative voltage (for example, VSS) may be applied to a source pattern of the first pull-down transistor PD1. A negative voltage (for example, VSS) may be applied to a source pattern of the second pull-down transistor PD2.

A drain pattern of the first pass transistor PG1, a drain pattern of the first pull-up transistor PU1, and a drain pattern of the first pull-down transistor PD1 may be electrically connected to a first node N1.

A drain pattern of the second pass transistor PG2, a drain pattern of the second pull-up transistor PU2, and a drain pattern of the second pull-down transistor PD2 may be electrically connected to a second node N2.

A switching electrode (for example, a gate electrode) of the first pull-up transistor PU1 and a switching electrode (for example, a gate electrode) of the first pull-down transistor PD1 may be electrically connected to the second node N2. A switching electrode (for example, a gate electrode) of the second pull-up transistor PU2 and a switching electrode (for example, a gate electrode) of the second pull-down transistor PD2 may be electrically connected to the first node N1. Accordingly, the first and second pull-up transistors PU1, PU2 and the first and second pull-down transistors PD1, PD2 may form a latch circuit configured of a pair of CMOS inverters.

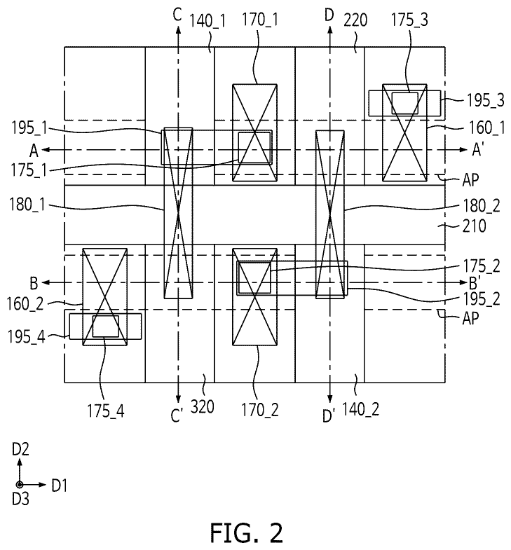

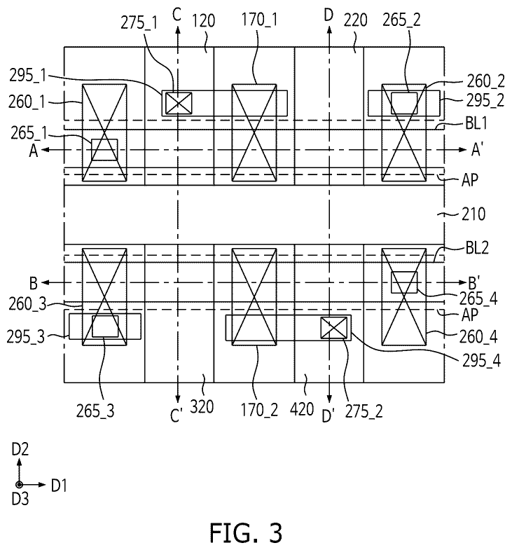

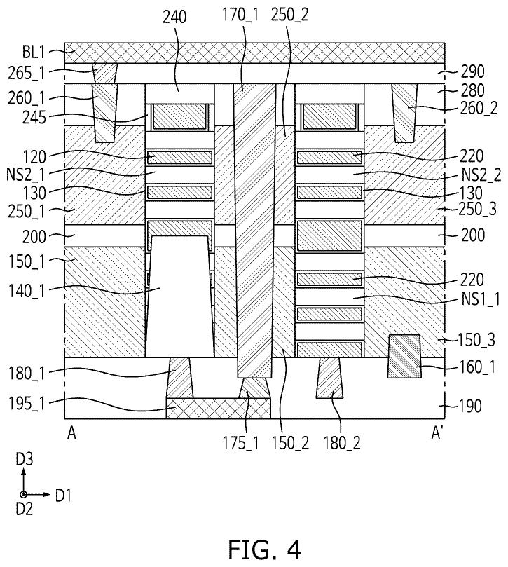

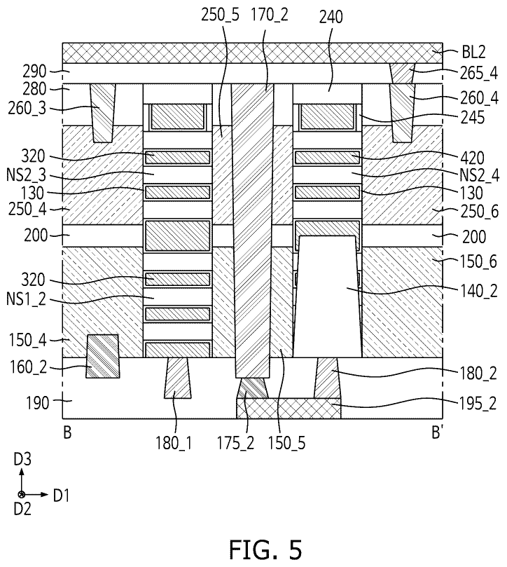

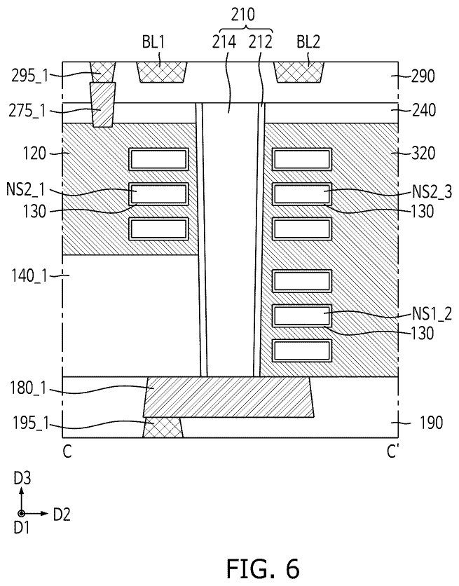

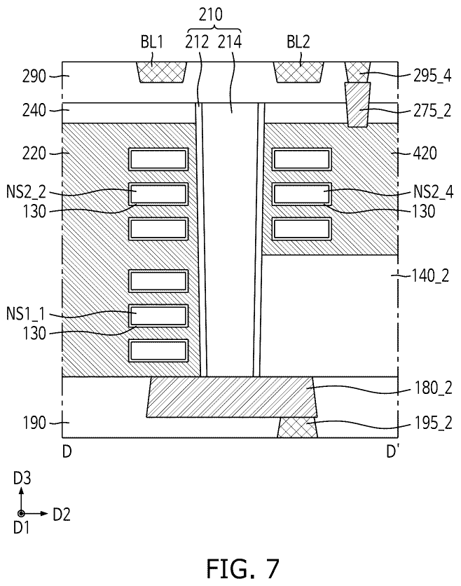

FIGS. 2 and 3 are exemplary plan views illustrating a semiconductor device according to some embodiments of the present disclosure. FIG. 4 is a cross-sectional view taken along line A-A′ of FIGS. 2 and 3. FIG. 5 is a cross-sectional view taken along line B-B′ of FIGS. 2 and 3. FIG. 6 is a cross-sectional view taken along line C-C′ of FIGS. 2 and 3. FIG. 7 is a cross-sectional view taken along line D-D′ of FIGS. 2 and 3. For reference, FIG. 2 is mainly shown focusing on a lower source/drain contact 160_1, 160_2, a lower gate contact 180_1, 180_2, and lower line wiring 195_1, 195_2, 195_3, 195_4, while FIG. 3 is mainly shown focusing on an upper source/drain contact 260_1, 260_2, 260_3, 260_4, an upper line wiring 295_1, 295_2, 295_3, 295_4, and bit lines BL1, BL2.

Referring to FIGS. 2-7, according to some embodiments, the semiconductor device may include separation insulating layers 140_1, 140_2, a plurality of lower sheet patterns NS1_1, NS1_2, a plurality of upper sheet patterns NS2_1, NS2_2, NS2_3, NS2_4, gate electrodes 120, 220, 320, 420, lower source/drain patterns 150_1, 150_2, 150_3, 150_4, 150_5, 150_6, upper source/drain patterns 250_1, 250_2, 250_3, 250_4, 250_5, 250_6, through contacts 170_1, 170_2, lower gate contacts 180_1, 180_2, lower vias 175_1, 175_2, lower source/drain contacts 160_1, 160_2, lower line wiring 195_1, 195_2, 195_3, 195_4, upper source/drain contacts 260_1, 260_2, 260_3, 260_4, upper gate contacts 275_1, 275_2, upper vias 265_1, 265_2, upper line wiring 295_1, 295_2, 295_3, 295_4, bit lines BL1, BL2, and a gate separation structure 210.

An active region AP may be disposed on a lower wiring insulating layer 190. The active region AP may be a region in which a plurality of lower sheet patterns NS1_1, NS1_2 and a plurality of upper sheet patterns NS2_1, NS2_2, NS2_3, NS2_4, and the lower source/drain patterns 150_1, 150_2, 150_3, 150_4, 150_5, 150_6 and the upper source/drain patterns 250_1, 250_2, 250_3, 250_4, 250_5, 250_6 are disposed. The active region AP may extend in a first direction D1. The first direction D1 may intersect a second direction D2. For example, the first direction D1 may be perpendicular to the second direction D2. A third direction D3 may intersect each of the first direction D1 and the second direction D2. For example, the third direction D3 may be perpendicular to each of the first direction D1 and the second direction D2. The first direction D1 and the second direction D2 may be directions parallel to an upper surface of the lower wiring insulating layer 190, and the third direction D3 may be a direction perpendicular to the upper surface of the lower wiring insulating layer 190.

A first separation insulating layer 140_1 may be disposed on the lower wiring insulating layer 190. The first separation insulating layer 140_1 may be disposed between the first lower source/drain pattern 150_1 and the second lower source/drain pattern 150_2. The first gate electrode 120 may be disposed on the first separation insulating layer 140_1. The first separation insulating layer 140_1 may be spaced apart in the second direction D2 from the plurality of second lower sheet patterns NS1_2. An upper surface of the first separation insulating layer 140_1 may contact the first gate electrode 120.

A plurality of first upper sheet patterns NS2_1 may be disposed on the active region AP. The plurality of first upper sheet patterns NS2_1 may be spaced apart in the third direction D3 from the first separation insulating layer 140_1. Each of the plurality of first upper sheet patterns NS2_1 may have a nano-sheet shape. The plurality of first upper sheet patterns NS2_1 may be spaced from one another in the third direction D3. Although three first upper sheet patterns NS2_1 are shown, the present disclosure is not limited thereto.

A plurality of first lower sheet patterns NS1_1 may be disposed on the active region AP. The plurality of first lower sheet patterns NS1_1 may be spaced apart in the first direction D1 from the first separation insulating layer 140_1. A second lower source/drain pattern 150_2 may be disposed between the plurality of first lower sheet patterns NS1_1 and the first separation insulating layer 140_1. Each of the plurality of first lower sheet patterns NS1_1 may have a nano-sheet shape. The plurality of first lower sheet patterns NS1_1 may be spaced apart from one another in the third direction D3. Although three first lower sheet patterns NS1_1 are shown, the present disclosure is not limited thereto.

A plurality of second upper sheet patterns NS2_2 may be disposed on the active region AP. The plurality of second upper sheet patterns NS2_2 may be disposed on the plurality of first lower sheet patterns NS1_1. The plurality of second upper sheet patterns NS2_2 may be spaced apart in the third direction D3 from the plurality of first lower sheet patterns NS1_1. The plurality of second upper sheet patterns NS2_2 may be spaced apart in the first direction D1 from the plurality of first upper sheet patterns NS2_1. Each of the plurality of second upper sheet patterns NS2_2 may have a nano-sheet shape. The plurality of second upper sheet patterns NS2_2 may be spaced apart from one another in the third direction D3. Although three second upper sheet patterns NS2_2 are shown, the present disclosure is not limited thereto.

A plurality of second lower sheet patterns NS1_2 may be disposed on the active region AP. The plurality of second lower sheet patterns NS1_2 may be spaced apart in the third direction D3 from the lower wiring insulating layer 190. A fifth lower source/drain pattern 150_5 may be disposed between the plurality of second lower sheet patterns NS1_2 and the second separation insulating layer 140_2. Each of the plurality of second lower sheet patterns NS1_2 may have a nano-sheet shape. The plurality of second lower sheet patterns NS1_2 may be spaced apart from one another in the third direction D3. Although three second lower sheet patterns NS1_2 are shown, the present disclosure is not limited thereto.

A plurality of third upper sheet patterns NS2_3 may be disposed on the active region AP. The plurality of third upper sheet patterns NS2_3 may be disposed on the plurality of second lower sheet patterns NS1_2. The plurality of third upper sheet patterns NS2_3 may be spaced apart in the third direction D3 from the plurality of second lower sheet patterns NS1_2. The plurality of third upper sheet patterns NS2_3 may be spaced apart in the second direction D2 from the plurality of first upper sheet patterns NS2_1. Each of the plurality of third upper sheet patterns NS2_3 may have a nano-sheet shape. The plurality of third upper sheet patterns NS2_3 may be spaced apart from one another in the third direction D3. Although three third upper sheet patterns NS2_3 are shown, the present disclosure is not limited thereto.

A second separation insulating layer 140_2 may be disposed on the lower wiring insulating layer 190. The second separation insulating layer 140_2 may be disposed between the fifth lower source/drain pattern 150_5 and the sixth lower source/drain pattern 150_6. The fourth gate electrode 420 may be disposed on the second separation insulating layer 140_2. The second separation insulating layer 140_2 may be spaced apart from the plurality of first lower sheet patterns NS1_1 in the second direction D2. An upper surface of the second separation insulating layer 140_2 may contact the fourth gate electrode 420.

A plurality of fourth upper sheet patterns NS2_4 may be disposed on the active region AP. The plurality of fourth upper sheet patterns NS2_4 may be spaced apart in the third direction D3 from the second separation insulating layer 140_2. The plurality of fourth upper sheet patterns NS2_4 may be spaced apart in the second direction D2 from the plurality of second upper sheet patterns NS2_2. Each of the plurality of fourth upper sheet patterns NS2_4 may have a nano-sheet shape. The plurality of fourth upper sheet patterns NS2_4 may be spaced apart from one another in the third direction D3.

Although three fourth upper sheet patterns NS2_4 are shown, the present disclosure is not limited thereto.

Each of the first separation insulating layer 140_1 and the second separation insulating layer 140_2 may include an insulating material. For example, each of the first separation insulating layer 140_1 and the second separation insulating layer 140_2 may include silicon nitride (SiN), silicon oxynitride (SiON), silicon oxycarbonitride (SiOCN), or silicon carbonitride (SiCN).

Each of the lower sheet patterns NS1_1, NS1_2 and the upper sheet patterns NS2_1, NS2_2, NS2_3, NS2_4 may include one of a group consisting of a single-element semiconductor material such as silicon (Si), silicon germanium (SiGe), an IV-IV compound semiconductor, or a III-V compound semiconductor.

The IV-IV compound semiconductor may be, for example, a binary compound or ternary compound including at least two or more of carbon (C), silicon (Si), germanium (Ge), and tin (Sn).

The III-V compound semiconductor may be, for example, one of a binary compound, ternary compound, or quaternary compound formed by combining at least one of aluminum (Al), gallium (Ga), or indium (In) of group III with one of phosphorus (P), arsenic (As), and antimony (Sb) of group V.

In some embodiments, the plurality of first upper sheet patterns NS2_1 may form a channel region of a first pass transistor (for example, PG1 of FIG. 1). The plurality of second upper sheet patterns NS2_2 may form a channel region of a first pull-down transistor (for example, PD1 of FIG. 1). The plurality of third upper sheet patterns NS2_3 may form a channel region of a second pull-down transistor (for example, PD2 of FIG. 1). The plurality of fourth upper sheet patterns NS2_4 may form a channel region of a second pass transistor (for example, PG2 of FIG. 1). The plurality of first lower sheet patterns NS1_1 may form a channel region of a first pull-up transistor (for example, PU1 of FIG. 1). The plurality of second lower sheet patterns NS1_2 may form a channel region of a second pull-up transistor (for example, PU2 of FIG. 1).

The first gate electrode 120 may be disposed on the first separation insulating layer 140_1. The first gate electrode 120 may extend in the second direction D2. The first gate electrode 120 may intersect the active region AP. The first gate electrode 120 may surround the plurality of first upper sheet patterns NS2_1. For example, the first gate electrode 120 may surround four surfaces of each first upper sheet pattern NS2_1.

The second gate electrode 220 may be disposed on the lower wiring insulating layer 190. The second gate electrode 220 may extend in the second direction D2. The second gate electrode 220 may be spaced apart from the first gate electrode 120 in the first direction D1. The second gate electrode 220 may intersect the active region AP. The second gate electrode 220 may surround the plurality of first lower sheet patterns NS1_1 and the plurality of second upper sheet patterns NS2_2. For example, the second gate electrode 220 may surround four surfaces of each first lower sheet pattern NS1_1 and second upper sheet pattern NS2_1.

The third gate electrode 320 may be disposed on the lower wiring insulating layer 190. The third gate electrode 320 may extend in the second direction D2. The third gate electrode 320 may be spaced apart from the first gate electrode 120 in the second direction D2. The first gate electrode 120 may overlap the third gate electrode 320 in the second direction D2. A gate separation structure 210 may be disposed between the third gate electrode 320 and the first gate electrode 120.

The third gate electrode 320 may intersect the active region AP. The third gate electrode 320 may surround the plurality of second lower sheet patterns NS1_2 and the plurality of third upper sheet patterns NS2_3. For example, the third gate electrode 320 may surround four surfaces of each second lower sheet pattern NS1_2 and third upper sheet pattern NS2_3.

The fourth gate electrode 420 may be disposed on the second separation insulating layer 140_2. The fourth gate electrode 420 may extend in the second direction D2. The fourth gate electrode 420 may be spaced apart in the second direction D2 from the second gate electrode 220. The fourth gate electrode 420 may overlap the second gate electrode 220 in the second direction D2. The gate separation structure 210 may be disposed between the fourth gate electrode 420 and the second gate electrode 220.

The fourth gate electrode 420 may intersect the active region AP. The fourth gate electrode 420 may surround the plurality of fourth upper sheet patterns NS2_4. For example, the fourth gate electrode 420 may surround four surfaces of each fourth upper sheet pattern NS2_4.

The gate electrodes 120, 220, 320, 420 may include at least one of a metal, a metal alloy, a conductive metal nitride, a metal silicide, a doped semiconductor material, a conductive metal oxide, or a conductive metal oxynitride. For example, the gate electrodes 120, 220, 320, 420 may include at least one of titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlC-N), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel platinum (Ni-Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), or combinations thereof, without being limited thereto. The conductive metal oxide and conductive metal oxynitride may include oxidized forms of the above materials, but the present disclosure is not limited thereto.

The gate separation structure 210 may be disposed on the lower wiring insulating layer 190. The gate separation structure 210 may extend in the first direction D1 and the third direction D3. The gate separation structure 210 may be disposed between the first gate electrode 120 and the third gate electrode 320 and between the first separation insulating layer 140_1 and the third gate electrode 320. The gate separation structure 210 may be disposed between the second gate electrode 220 and the fourth gate electrode 420 and between the second gate electrode 220 and the second separation insulating layer 140_2.

In some embodiments, a width of the gate separation structure 210 in the second direction D2 may not be uniform. For example, the width of the gate separation structure 210 in the second direction D2 may increase as the gate separation structure 210 becomes farther from the lower wiring insulating layer 190. The gate separation structure 210 may include an inclined side surface. However, the present disclosure is not limited thereto.

The gate separation structure 210 may include a liner film 212 and a filling insulating film 214. The liner film 212 may define side surfaces of the gate separation structure 210. The filling insulating film 214 may be disposed within the liner film 212. The liner film 212 may include, for example, silicon nitride (SiN), silicon oxynitride (SiON), silicon oxycarbonitride (SiOCN), silicon boron nitride (SiBN), silicon oxyboron nitride (SiOBN), or silicon carbonitride (SiCN). The filling insulating film 214 may include, for example, silicon oxide (SiO2), silicon oxynitride (SiON), silicon oxycarbonitride (SiOCN), silicon oxyboron nitride (SiOBN), silicon oxycarbide (SiOC), or combinations thereof.

A gate insulating film 130 may be disposed between the plurality of first upper sheet patterns NS2_1 and the first gate electrode 120. The gate insulating film 130 may be disposed between the plurality of second upper sheet patterns NS2_2 and the second gate electrode 220 and between the plurality of first lower sheet patterns NS1_1 and the second gate electrode 220. The gate insulating film 130 may be disposed between the plurality of third upper sheet patterns NS2_3 and the third gate electrode 320 and between the plurality of second lower sheet patterns NS1_2 and the third gate electrode 320. The gate insulating film 130 may be disposed between the plurality of fourth upper sheet patterns NS2_4 and the fourth gate electrode 420.

In some embodiments, the gate insulating film 130 may include a plurality of layers. For example, the gate insulating film 130 may include an interfacial insulating film and a high-k insulating film. The interfacial insulating film may include, for example, silicon oxide. The high-k insulating film may include a high-k material having a dielectric constant greater than the interfacial insulating film. The high-k insulating film may include, for example, boron nitride, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, or lead zinc niobate.

A gate spacer 245 may be disposed on side surfaces of the first to fourth gate electrodes 120, 220, 320, 420. For convenience of explanation, a description will be made focusing on the first gate electrode 120. For example, the gate spacer 245 may be disposed on both side surfaces of the first gate electrode 120, which is disposed on upper surfaces of the uppermost first upper sheet patterns NS2_1. The gate spacer 245 may extend along side surfaces of the first gate electrode 120. The gate spacer 245 may not be disposed between the first upper sheet patterns NS2_1 adjacent to one another in the third direction D3.

The gate spacer 245 may include, for example, at least one of silicon nitride (SiN), silicon oxynitride (SiON), silicon oxide (SiO2), silicon oxycarbonitride (SiOCN), silicon boron nitride (SiBN), silicon oxyboron nitride (SiOBN), silicon oxycarbide (SiOC), or combinations thereof. Although the gate spacer 245 is shown as a single layer, this is merely for convenience of explanation, and the present disclosure is not limited thereto.

A gate capping pattern 240 may be disposed on upper surfaces of the first to fourth gate electrodes 120, 220, 320, 420. The gate capping pattern 240 may cover upper surfaces of the first to fourth gate electrodes 120, 220, 320, 420. Although it is shown that the gate capping pattern 240 contacts upper surfaces of the gate spacer 245, the present disclosure is not limited thereto. For example, the gate capping pattern 240 may be disposed between a pair of gate spacers 245 and may contact side surfaces of the gate spacer 245.

The gate capping pattern 240 may include, for example, at least one of silicon nitride (SiN), silicon oxynitride (SiON), silicon carbonitride (SiCN), or silicon oxycarbonitride (SiOCN). The gate capping pattern 240 may include a material having an etch selectivity relative to an upper interlayer insulating film 280.

The upper interlayer insulating film 280 may be disposed on upper surfaces of the first to sixth upper source/drain patterns 250_1, 250_2, 250_3, 250_4, 250_5, 250_6. The upper interlayer insulating film 280 may cover upper surfaces of the first to sixth upper source/drain patterns 250_1, 250_2, 250_3, 250_4, 250_5, 250_6. Contrary to what is shown, in some embodiments, an etch stop film may be disposed between the upper interlayer insulating film 280 and the upper surfaces of the first to sixth upper source/drain patterns 250_1, 250_2, 250_3, 250_4, 250_5, 250_6.

The upper interlayer insulating film 280 may include, for example, at least one of silicon oxide (SiO), silicon nitride (SiN), silicon oxynitride (SiON), or a low-k material. The low-k material may include, for example, Fluorinated TetraEthylOrthoSilicate (FTEOS), Hydrogen SilsesQuioxane (HSQ), Bis-benzoCycloButene (BCB), TetraMethylOrthoSilicate (TMOS), OctaMethylCyCloTetraSiloxane (OMCTS), HexaMethylDiSiloxane (HMDS), TriMethylSilyl Borate (TMSB), DiAcetoxyDitertiary ButoSiloxane (DADBS), TriMethylSilil Phosphate (TMSP), PolyTetraFluoroEthylene (PTFE), TOSZ (Tonen SilaZen), FSG (Fluoride Silicate Glass), polypropylene oxide-based polyimide nanofoams, CDO (Carbon Doped silicon Oxide), OSG (Organo Silicate Glass), SiLK, Amorphous Fluorinated Carbon, silica aerogels, silica xerogels, mesoporous silica, or combinations thereof, without being limited thereto.

The first lower source/drain pattern 150_1, the second lower source/drain pattern 150_2, and the third lower source/drain pattern 150_3 each may be disposed on the lower wiring insulating layer 190. The first lower source/drain pattern 150_1, the second lower source/drain pattern 150_2, and the third lower source/drain pattern 150_3 may be spaced apart from one another in the first direction D1.

The first lower source/drain pattern 150_1 may be disposed on one side of the first separation insulating layer 140_1. The second lower source/drain pattern 150_2 may be disposed on the other side of the first separation insulating layer 140_1. The second lower source/drain pattern 150_2 may be disposed on side surfaces of the plurality of first lower sheet patterns NS1_1. The third lower source/drain pattern 150_3 may be disposed on side surfaces of the plurality of first lower sheet patterns NS1_1. For example, the second lower source/drain pattern 150_2 and the third lower source/drain pattern 150_3 may be disposed on both sides of the plurality of first lower sheet patterns NS1_1. The second lower source/drain pattern 150_2 and the third lower source/drain pattern 150_3 may be connected to the plurality of first lower sheet patterns NS1_1.

The fourth lower source/drain pattern 150_4, the fifth lower source/drain pattern 150_5, and the sixth lower source/drain pattern 150_6 each may be disposed on the lower wiring insulating layer 190. The fourth lower source/drain pattern 150_4, the fifth lower source/drain pattern 150_5, and the sixth lower source/drain pattern 150_6 may be spaced apart from one another in the first direction D1.

The fourth lower source/drain pattern 150_4 may be disposed on side surfaces of the plurality of second lower sheet patterns NS1_2. The fifth lower source/drain pattern 150_5 may be disposed on side surfaces of the plurality of second lower sheet patterns NS1_2. For example, the fourth lower source/drain pattern 150_4 and the fifth lower source/drain pattern 150_5 may be disposed on both sides of the plurality of second lower sheet patterns NS1_2. The fourth lower source/drain pattern 150_4 and the fifth lower source/drain pattern 150_5 may be connected to the plurality of second lower sheet patterns NS1_2. The fifth lower source/drain pattern 150_5 may be disposed on one side of the second separation insulating layer 140_2. The sixth lower source/drain pattern 150_6 may be disposed on the other side of the second separation insulating layer 140_2.

The first upper source/drain pattern 250_1 may be spaced apart in the third direction D3 from the first lower source/drain pattern 150_1. A middle insulating film 200 may be disposed between the first upper source/drain pattern 250_1 and the first lower source/drain pattern 150_1. The first upper source/drain pattern 250_1 may be disposed on side surfaces of the plurality of first upper sheet patterns NS2_1.

The second upper source/drain pattern 250_2 may be spaced apart in the third direction D3 from the second lower source/drain pattern 150_2. A middle insulating film 200 may be disposed between the second upper source/drain pattern 250_2 and the second lower source/drain pattern 150_2. The second upper source/drain pattern 250_2 may be disposed on side surfaces of the plurality of first upper sheet patterns NS2_1 and the plurality of second upper sheet patterns NS2_2.

The third upper source/drain pattern 250_3 may be spaced apart in the third direction D3 from the third lower source/drain pattern 150_3. A middle insulating film 200 may be disposed between the third upper source/drain pattern 250_3 and the third lower source/drain pattern 150_3. The third upper source/drain pattern 250_3 may be disposed on side surfaces of the plurality of second upper sheet patterns NS2_2.

The first upper source/drain pattern 250_1, the second upper source/drain pattern 250_2, and the third upper source/drain pattern 250_3 may be spaced apart from one another in the first direction D1. The first upper source/drain pattern 250_1 and the second upper source/drain pattern 250_2 may be disposed on both sides of the plurality of first upper sheet patterns NS2_1. The second upper source/drain pattern 250_2 and the third upper source/drain pattern 250_3 may be disposed on both sides of the plurality of second upper sheet patterns NS2_2.

The fourth upper source/drain pattern 250_4 may be spaced apart in the third direction D3 from the fourth lower source/drain pattern 150_4. A middle insulating film 200 may be disposed between the fourth upper source/drain pattern 250_4 and the fourth lower source/drain pattern 150_4. The fourth upper source/drain pattern 250_4 may be disposed on side surfaces of the plurality of third upper sheet patterns NS2_3.

The fifth upper source/drain pattern 250_5 may be spaced apart in the third direction D3 from the fifth lower source/drain pattern 150_5. A middle insulating film 200 may be disposed between the fifth upper source/drain pattern 250_5 and the fifth lower source/drain pattern 150_5. The fifth upper source/drain pattern 250_5 may be disposed on side surfaces of the plurality of third upper sheet patterns NS2_3 and the plurality of fourth upper sheet patterns NS2_4.

The sixth upper source/drain pattern 250_6 may be spaced apart from the sixth lower source/drain pattern 150_6 in the third direction D3. A middle insulating film 200 may be disposed between the sixth upper source/drain pattern 250_6 and the sixth lower source/drain pattern 150_6. The sixth upper source/drain pattern 250_6 may be disposed on side surfaces of the plurality of fourth upper sheet patterns NS2_4.

The fourth upper source/drain pattern 250_4, the fifth upper source/drain pattern 250_5, and the sixth upper source/drain pattern 250_6 may be spaced apart from one another in the first direction D1. The fourth upper source/drain pattern 250_4 and the fifth upper source/drain pattern 250_5 may be disposed on both sides of the plurality of third upper sheet patterns NS2_3. The fifth upper source/drain pattern 250_5 and the sixth upper source/drain pattern 250_6 may be disposed on both sides of the plurality of fourth upper sheet patterns NS2_4.

Descriptions of materials of each of the first to sixth lower source/drain patterns 150_1, 150_2, 150_3, 150_4, 150_5, 150_6 and the first to sixth upper source/drain patterns 250_1, 250_2, 250_3, 250_4, 250_5, 250_6 that are identical may be replaced with the description of the first lower source/drain pattern 150_1.

The first lower source/drain pattern 150_1 may include an epitaxial pattern. The first lower source/drain pattern 150_1 may include a semiconductor material. The first lower source/drain pattern 150_1 may include, for example, single-element semiconductor material such as silicon (Si) or germanium (Ge). In addition, for example, the first lower source/drain pattern 150_1 may include a binary compound or ternary compound including at least two or more of carbon (C), silicon (Si), germanium (Ge), and tin (Sn), or a compound doped with group IV elements. For example, the first lower source/drain pattern 150_1 may include silicon (Si), silicon-germanium (SiGe), germanium (Ge), silicon carbide (SiC), or the like, but the present disclosure is not limited thereto.

In some embodiments, the first to sixth lower source/drain patterns 150_1, 150_2, 150_3, 150_4, 150_5, 150_6 may have a first conductivity type, and the first to sixth upper source/drain patterns 250_1, 250_2, 250_3, 250_4, 250_5, 250_6 may have a second conductivity type. The second conductivity type may be different from the first conductivity type. In some embodiments, the first conductivity type may be P-type, and the second conductivity type may be N-type. However, the present disclosure is not limited thereto. For example, the first conductivity type may be N-type, and the second conductivity type may be P-type.

Although each of the first to sixth lower source/drain patterns 150_1, 150_2, 150_3, 150_4, 150_5, 150_6 and the first to sixth upper source/drain patterns 250_1, 250_2, 250_3, 250_4, 250_5, 250_6 is illustrated as a single layer, this is merely for convenience of description and is not limited thereto. In an embodiment, each of the first to sixth lower source/drain patterns 150_1, 150_2, 150_3, 150_4, 150_5, 150_6 and the first to sixth upper source/drain patterns 250_1, 250_2, 250_3, 250_4, 250_5, 250_6 may include a plurality of layers having different materials. In another embodiment, each of the first to sixth lower source/drain patterns 150_1, 150_2, 150_3, 150_4, 150_5, 150_6 and the first to sixth upper source/drain patterns 250_1, 250_2, 250_3, 250_4, 250_5, 250_6 may include the same material but include multiple layers with different concentrations of the constituent material.

In some embodiments, the first lower source/drain pattern 150_1 may be omitted. For example, the first lower source/drain pattern 150_1 may be omitted and replaced with an insulating material. In some embodiments, the sixth lower source/drain pattern 150_6 may be omitted. For example, the sixth lower source/drain pattern 150_6 may be omitted and replaced with an insulating material.

The description of the material of the middle insulating film 200 may be the same as that described for the upper interlayer insulating film 280.

The first through contact 170_1 may extend in the third direction D3. The first through contact 170_1 may penetrate the upper interlayer insulating film 280, the middle insulating film 200, at least a portion of the second upper source/drain pattern 250_2, and at least a portion of the second lower source/drain pattern 150_2. For example, the first through contact 170_1 may penetrate the upper and lower surfaces of the second upper source/drain pattern 250_2 and the upper and lower surfaces of the second lower source/drain pattern 150_2. A lower surface of the first through contact 170_1 may be disposed in the lower wiring insulating layer 190.

In some embodiments, a width of the first through contact 170_1 in the first direction D1 may not be uniform. For example, the width of the first through contact 170_1 in the first direction D1 may decrease as it becomes farther from the first bit line BL1. In other words, the first through contact 170_1 may have an inclined side surface. However, the present disclosure is not limited thereto. For example, the width of the first through contact 170_1 in the first direction D1 may be uniform.

A first lower gate contact 180_1 may be disposed in the lower wiring insulating layer 190. The first lower gate contact 180_1 may be disposed on a lower surface of the third gate electrode 320. The first lower gate contact 180_1 may be connected to the third gate electrode 320. The first lower gate contact 180_1 may extend in the second direction D2. The first separation insulating layer 140_1, the gate separation structure 210, and the third gate electrode 320 may be disposed on an upper surface of the first lower gate contact 180_1. A portion of the first lower gate contact 180_1 may overlap the first separation insulating layer 140_1 in the third direction D3.

A first lower via 175_1 may be disposed in the lower wiring insulating layer 190. The first lower via 175_1 may be disposed on a lower surface of the first through contact 170_1. The first lower via 175_1 may be connected to the first through contact 170_1. In some embodiments, a lower surface of the first lower via 175_1 and a lower surface of the first lower gate contact 180_1 may be disposed at the same vertical level.

In the present disclosure, the vertical level may refer to the vertical level in the third direction D3. The vertical level may represent the distance, in the third direction D3, from a reference level to a surface of a specific structure. The reference level may be a vertical level corresponding to an upper surface or lower surface of an arbitrary structure (for example, the upper surface or lower surface of the lower wiring insulating layer 190 or the bit lines BL1, BL2) having a planar surface.

A first lower line wiring 195_1 may be disposed on the lower surface of the first lower via 175_1 and the lower surface of the first lower gate contact 180_1. The first lower line wiring 195_1 may be disposed in the lower wiring insulating layer 190. The first lower line wiring 195_1 may extend in the first direction D1. The first lower line wiring 195_1 may connect the first lower via 175_1 and the first lower gate contact 180_1. The first lower gate contact 180_1 may be electrically connected to the first through contact 170_1. For example, the first lower gate contact 180_1 may be electrically connected to the first through contact 170_1 through the first lower line wiring 195_1 and the first lower via 175_1. That is, the third gate electrode 320 may be electrically connected to each of the second lower source/drain pattern 150_2 and the second upper source/drain pattern 250_2 via the first lower gate contact 180_1, the first lower line wiring 195_1, the first lower via 175_1, and the first through contact 170_1.

In the present disclosure, the phrase “a configuration is connected to another configuration” may include physical and electrical connections. In addition, the phrase “a configuration is electrically connected to another configuration” may include both direct electrical connection and indirect electrical connection through another configuration between the two.

A second through contact 170_2 may be spaced apart in the second direction D2 from the first through contact 170_1. The second through contact 170_2 may extend in the third direction D3. The second through contact 170_2 may penetrate the upper interlayer insulating film 280, the middle insulating film 200, at least a portion of the fifth upper source/drain pattern 250_5, and at least a portion of the fifth lower source/drain pattern 150_5. For example, the second through contact 170_2 may penetrate the upper and lower surfaces of the fifth upper source/drain pattern 250_5 and the upper and lower surfaces of the fifth lower source/drain pattern 150_5. A lower surface of the second through contact 170_2 may be disposed in the lower wiring insulating layer 190.

In some embodiments, a width of the second through contact 170_2 in the first direction D1 may not be uniform. For example, the width of the second through contact 170_2 in the first direction D1 may decrease as it becomes farther from the second bit line BL2. In other words, the second through contact 170_2 may have an inclined side surface. However, the present disclosure is not limited thereto. For example, the width of the second through contact 170_2 in the first direction D1 may be uniform.

A second lower gate contact 180_2 may be disposed in the lower wiring insulating layer 190. The second lower gate contact 180_2 may be spaced apart in the first direction D1 from the first lower gate contact 180_1. The second lower gate contact 180_2 may overlap the first lower gate contact 180_1 in the first direction D1. The second lower gate contact 180_2 may be disposed at the same vertical level as the first lower gate contact 180_1.

The second lower gate contact 180_2 may be disposed on a lower surface of the second gate electrode 220. The second lower gate contact 180_2 may be connected to the second gate electrode 220. The second lower gate contact 180_2 may extend in the second direction D2. The second separation insulating layer 140_2, the gate separation structure 210 (denoted “CT” in the figure), and the second gate electrode 220 may be disposed on an upper surface of the second lower gate contact 180_2. A portion of the second lower gate contact 180_2 may overlap the second separation insulating layer 140_2 in the third direction D3.

A second lower via 175_2 may be disposed in the lower wiring insulating layer 190. The second lower via 175_2 may be disposed on a lower surface of the second through contact 170_2. The second lower via 175_2 may be connected to the second through contact 170_2. In some embodiments, a lower surface of the second lower via 175_2 and a lower surface of the second lower gate contact 180_2 may be disposed at the same vertical level.

A second lower line wiring 195_2 may be disposed on the lower surface of the second lower via 175_2 and the lower surface of the second lower gate contact 180_2. The second lower line wiring 195_2 may be disposed in the lower wiring insulating layer 190. The second lower line wiring 195_2 may extend in the first direction D1. The second lower line wiring 195_2 may connect the second lower via 175_2 and the second lower gate contact 180_2. The second lower gate contact 180_2 may be electrically connected to the second through contact 170_2. For example, the second lower gate contact 180_2 may be electrically connected to the second through contact 170_2 through the second lower line wiring 195_2 and the second lower via 175_2. That is, the second gate electrode 220 may be electrically connected to each of the fifth lower source/drain pattern 150_5 and the fifth upper source/drain pattern 250_5 via the second lower gate contact 180_2, the second lower line wiring 195_2, the second lower via 175_2, and the second through contact 170_2.

Each of the first and second through contacts 170_1, 170_2 may include a conductive material. In some embodiments, each of the first through contact 170_1 and the second through contact 170_2 may include a contact barrier film and a filling conductive film. The contact barrier film may include, for example, any one of tantalum (Ta), tantalum nitride (TaN), titanium (Ti), titanium nitride (TiN), ruthenium (Ru), cobalt (Co), nickel (Ni), nickel boron (NiB), tungsten (W), tungsten nitride (WN), tungsten carbonitride (WCN), zirconium (Zr), zirconium nitride (ZrN), vanadium (V), vanadium nitride (VN), niobium (Nb), niobium nitride (NbN), platinum (Pt), iridium (Ir), and rhodium (Rh). The filling conductive film may include, for example, any one of aluminum (Al), tungsten (W), cobalt (Co), ruthenium (Ru), and molybdenum (Mo).

Each of the first lower gate contact 180_1 and the second lower gate contact 180_2 may include a conductive material. In some embodiments, each of the first lower gate contact 180_1 and the second lower gate contact 180_2 may include a contact barrier film and a filling conductive film. The description of the contact barrier film and the filling conductive film of the first lower gate contact 180_1 and the second lower gate contact 180_2 may be the same as that of the contact barrier film and the filling conductive film of the through contacts 170_1, 170_2.

A first lower source/drain contact 160_1 may be disposed on the third lower source/drain pattern 150_3. The first lower source/drain contact 160_1 may penetrate a lower surface of the third lower source/drain pattern 150_3. The first lower source/drain contact 160_1 may be connected to the third lower source/drain pattern 150_3.

A third lower via 175_3 may be disposed on a lower surface of the first lower source/drain contact 160_1. The third lower via 175_3 may be connected to the first lower source/drain contact 160_1. A third lower line wiring 195_3 may be disposed on a lower surface of the third lower via 175_3. The third lower line wiring 195_3 may extend in the first direction D1. The third lower line wiring 195_3 may be electrically connected to the third lower source/drain pattern 150_3. For example, the third lower line wiring 195_3 may be electrically connected to the third lower source/drain pattern 150_3 through the third lower via 175_3 and the first lower source/drain contact 160_1. In some embodiments, a VDD voltage of FIG. 1 may be supplied to the third lower line wiring 195_3.

A second lower source/drain contact 160_2 may be disposed on the fourth lower source/drain pattern 150_4. The second lower source/drain contact 160_2 may penetrate a lower surface of the fourth lower source/drain pattern 150_4. The second lower source/drain contact 160_2 may be connected to the fourth lower source/drain pattern 150_4.

A fourth lower via 175_4 may be disposed on a lower surface of the second lower source/drain contact 160_2. The fourth lower via 175_4 may be connected to the second lower source/drain contact 160_2. A fourth lower line wiring 195_4 may be disposed on a lower surface of the fourth lower via 175_4. The fourth lower line wiring 195_4 may extend in the first direction D1. The fourth lower line wiring 195_4 may be electrically connected to the fourth lower source/drain pattern 150_4. For example, the fourth lower line wiring 195_4 may be electrically connected to the fourth lower source/drain pattern 150_4 through the fourth lower via 175_4 and the second lower source/drain contact 160_2. In some embodiments, a VDD voltage of FIG. 1 may be supplied to the fourth lower line wiring 195_4.

In some embodiments, each of the first to fourth lower line wiring 195_1, 195_2, 195_3, 195_4 may be disposed at the same vertical level. The directions in which each of the first to fourth lower line wiring 195_1, 195_2, 195_3, 195_4 extends may be the same. For example, each of the first to fourth lower line wiring 195_1, 195_2, 195_3, 195_4 may extend in the first direction D1. Each of the first to fourth lower line wiring 195_1, 195_2, 195_3, 195_4 may include a conductive material. For example, each of the first to fourth lower line wiring 195_1, 195_2, 195_3, 195_4 may include any one of copper (Cu), tungsten (W), aluminum (Al), cobalt (Co), or molybdenum (Mo), without being limited thereto.

Each of the first lower source/drain contact 160_1 and the second lower source/drain contact 160_2 may include a conductive material. In some embodiments, each of the first lower source/drain contact 160_1 and the second lower source/drain contact 160_2 may include a contact barrier film and a filling conductive film. The description of the contact barrier film and the filling conductive film of each of the first lower source/drain contact 160_1 and the second lower source/drain contact 160_2 may be the same as that of the contact barrier film and the filling conductive film of the through contacts 170_1, 170_2.

A first upper source/drain contact 260_1 may be disposed on the first upper source/drain pattern 250_1. The first upper source/drain contact 260_1 may penetrate the upper interlayer insulating film 280 and an upper surface of the first upper source/drain pattern 250_1. The first upper source/drain contact 260_1 may be connected to the first upper source/drain pattern 250_1.

A first upper via 265_1 may be disposed in an upper wiring insulating layer 290. The first upper via 265_1 may be disposed on an upper surface of the first upper source/drain contact 260_1. The first bit line BL1 may be disposed on an upper surface of the first upper via 265_1. The first bit line BL1 may extend in the first direction D1. The first bit line BL1 may be electrically connected to the first upper source/drain pattern 250_1. For example, the first bit line BL1 may be electrically connected to the first upper source/drain pattern 250_1 through the first upper via 265_1 and the first upper source/drain contact 260_1. In some embodiments, the first bit line BL1 may correspond to the first bit line BL1 of FIG. 1.

A first upper gate contact 275_1 may be disposed on the first gate electrode 120. The first upper gate contact 275_1 may penetrate the gate capping pattern 240 and an upper surface of the first gate electrode 120. The first upper gate contact 275_1 may be connected to the first gate electrode 120.

A first upper line wiring 295_1 may be disposed on an upper surface of the first upper gate contact 275_1. The first upper line wiring 295_1 may extend in the first direction D1. The first upper line wiring 295_1 may be electrically connected to the first gate electrode 120. For example, the first upper line wiring 295_1 may be electrically connected to the first gate electrode 120 through the first upper gate contact 275_1. In some embodiments, the first upper line wiring 295_1 may correspond to the word line WL of FIG. 1.

A second upper source/drain contact 260_2 may be disposed on the third upper source/drain pattern 250_3. The second upper source/drain contact 260_2 may penetrate the upper interlayer insulating film 280 and an upper surface of the third upper source/drain pattern 250_3. The second upper source/drain contact 260_2 may be connected to the third upper source/drain pattern 250_3.

A second upper via 265_2 may be disposed in the upper wiring insulating layer 290. The second upper via 265_2 may be disposed on an upper surface of the second upper source/drain contact 260_2. A second upper line wiring 295_2 may be disposed on an upper surface of the second upper via 265_2. The second upper line wiring 295_2 may extend in the first direction D1. The second upper line wiring 295_2 may be electrically connected to the third upper source/drain pattern 250_3. For example, the second upper line wiring 295_2 may be electrically connected to the third upper source/drain pattern 250_3 through the second upper via 265_2 and the second upper source/drain contact 260_2. In some embodiments, a VSS voltage of FIG. 1 may be applied to the second upper line wiring 295_2.

A third upper source/drain contact 260_3 may be disposed on the fourth upper source/drain pattern 250_4. The third upper source/drain contact 260_3 may penetrate the upper interlayer insulating film 280 and an upper surface of the fourth upper source/drain pattern 250_4. The third upper source/drain contact 260_3 may be connected to the fourth upper source/drain pattern 250_4.

A third upper via 265_3 may be disposed in the upper wiring insulating layer 290. The third upper via 265_3 may be disposed on an upper surface of the third upper source/drain contact 260_3. A third upper line wiring 295_3 may be disposed on an upper surface of the third upper via 265_3. The third upper line wiring 295_3 may extend in the first direction D1. The third upper line wiring 295_3 may be electrically connected to the fourth upper source/drain pattern 250_4. For example, the third upper line wiring 295_3 may be electrically connected to the fourth upper source/drain pattern 250_4 through the third upper via 265_3 and the third upper source/drain contact 260_3. In some embodiments, a VSS voltage of FIG. 1 may be applied to the third upper line wiring 295_3.

A second upper gate contact 275_2 may be disposed on the fourth gate electrode 420. The second upper gate contact 275_2 may penetrate the gate capping pattern 240 and an upper surface of the fourth gate electrode 420. The second upper gate contact 275_2 may be connected to the fourth gate electrode 420.

A fourth upper line wiring 295_4 may be disposed on an upper surface of the second upper gate contact 275_2. The fourth upper line wiring 295_4 may extend in the first direction D1. The fourth upper line wiring 295_4 may be electrically connected to the fourth gate electrode 420. For example, the fourth upper line wiring 295_4 may be electrically connected to the fourth gate electrode 420 through the second upper gate contact 275_2. In some embodiments, the fourth upper line wiring 295_4 may correspond to the word line WL of FIG. 1.

A fourth upper source/drain contact 260_4 may be disposed on the sixth upper source/drain pattern 250_6. The fourth upper source/drain contact 260_4 may penetrate the upper interlayer insulating film 280 and an upper surface of the sixth upper source/drain pattern 250_6. The fourth upper source/drain contact 260_4 may be connected to the sixth upper source/drain pattern 250_6.

A fourth upper via 265_4 may be disposed in the upper wiring insulating layer 290. The fourth upper via 265_4 may be disposed on an upper surface of the fourth upper source/drain contact 260_4. The second bit line BL2 may be disposed on an upper surface of the fourth upper via 265_4. The second bit line BL2 may extend in the first direction D1. The second bit line BL2 may be electrically connected to the sixth upper source/drain pattern 250_6. For example, the second bit line BL2 may be electrically connected to the sixth upper source/drain pattern 250_6 through the fourth upper via 265_4 and the fourth upper source/drain contact 260_4. In some embodiments, the second bit line BL2 may correspond to the second bit line BL2 of FIG. 1.

Each of the first and second upper gate contacts 275_1, 275_2 and each of the first to fourth upper source/drain contacts 260_1, 260_2, 260_3, 260_4 may include a conductive material. In some embodiments, each of the first and second upper gate contacts 275_1, 275_2 and the first to fourth upper source/drain contacts 260_1, 260_2, 260_3, 260_4 may include a contact barrier film and a filling conductive film. The description of the contact barrier film and the filling conductive film of the first and second upper gate contacts 275_1, 275_2 and the first to fourth upper source/drain contacts 260_1, 260_2, 260_3, 260_4 may be the same as that of the contact barrier film and the filling conductive film of the through contacts 170_1, 170_2.

Each of the lower wiring insulating layer 190 and the upper wiring insulating layer 290 may include, for example, at least one of silicon oxide, silicon nitride, silicon oxynitride, or a low-k material. The low-k material may include, for example, Fluorinated TetraEthylOrthoSilicate (FTEOS), Hydrogen SilsesQuioxane (HSQ), Bis-benzoCycloButene (BCB), TetraMethylOrthoSilicate (TMOS), OctaMethylcyCloTetraSiloxane (OMCTS), HexaMethylDiSiloxane (HMDS), TriMethylSilyl Borate (TMSB), DiAcetoxyDitertiary ButoxySiloxane (DADBS), TriMethylSilil Phosphate (TMSP), PolyTetraFluoroEthylene (PTFE), TOSZ (Tonen SilaZen), FSG (Fluoride Silicate Glass), polypropylene oxide-based polyimide nanofoams, CDO (Carbon Doped silicon Oxide), OSG (Organo Silicate Glass), SiLK, Amorphous Fluorinated Carbon, silica aerogels, silica xerogels, mesoporous silica, or combinations thereof. However, the present disclosure is not limited thereto.

In some embodiments, each of the first and second bit lines BL1, BL2 and each of the first to fourth upper line wiring 295_1, 295_2, 295_3, 295_4 may be disposed at the same vertical level. The directions in which each of the first and second bit lines BL1, BL2 and the first to fourth upper line wiring 295_1, 295_2, 295_3, 295_4 extends may be the same. For example, each of the first and second bit lines BL1, BL2 and the first to fourth upper line wiring 295_1, 295_2, 295_3, 295_4 may extend in the first direction D1.

In the semiconductor device according to some embodiments of the present disclosure, the third gate electrode 320 may be electrically connected to the first through contact 170_1 via the first lower gate contact 180_1, the first lower line wiring 195_1, and the first lower via 175_1. In addition, the second gate electrode 220 may be electrically connected to the second through contact 170_2 via the second lower gate contact 180_2, the second lower line wiring 195_2, and the second lower via 175_2. Accordingly, the degree of integration of the semiconductor device may be improved.

In the semiconductor device according to some embodiments of the present disclosure, the first to fourth lower line wiring 195_1, 195_2, 195_3, 195_4 may be disposed at the same vertical level in the lower wiring insulating layer 190, and the first and second bit lines BL1, BL2 and the first to fourth upper line wiring 295_1, 295_2, 295_3, 295_4 may be disposed at the same vertical level in the upper wiring insulating layer 290. In other words, by vertically separating the wiring constituting the SRAM, the degree of integration of the semiconductor device may be improved.

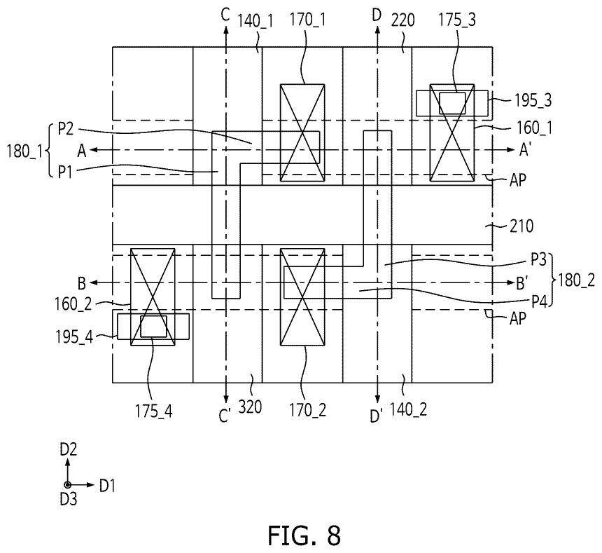

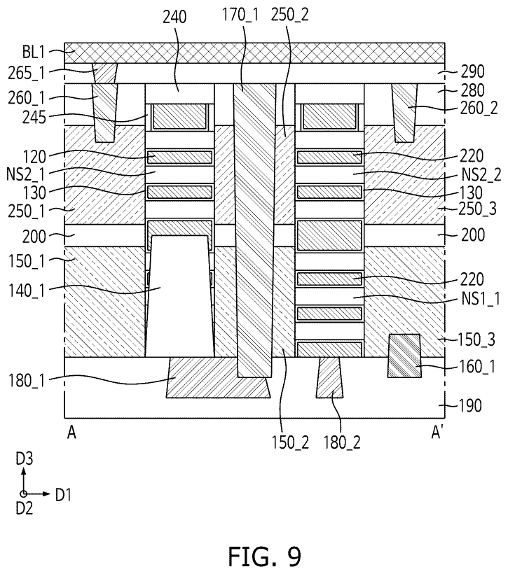

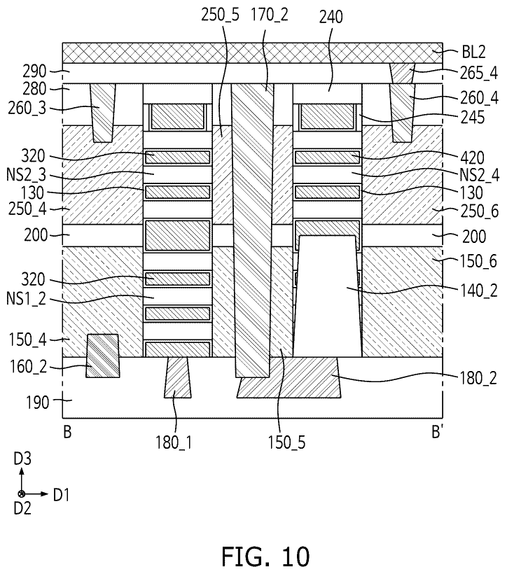

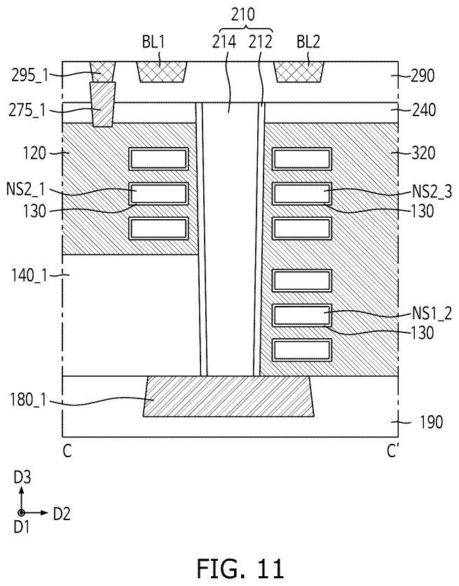

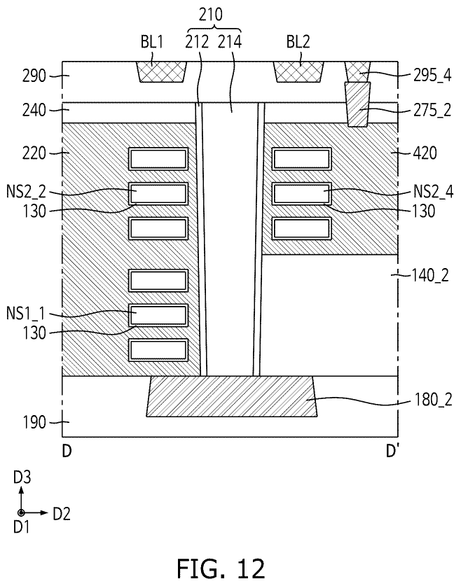

FIG. 8 is an exemplary plan view illustrating a semiconductor device according to some embodiments of the present disclosure. FIG. 9 is a cross-sectional view taken along line A-A′ of FIG. 8. FIG. 10 is a cross-sectional view taken along line B-B′ of FIG. 8. FIG. 11 is a cross-sectional view taken along line C-C′ of FIG. 8. FIG. 12 is a cross-sectional view taken along line D-D′ of FIG. 8. For convenience of explanation, descriptions will be made focusing on components different from those described with reference to FIGS. 2-7.

Referring to FIGS. 8-12, in the semiconductor device according to some embodiments, the first lower gate contact 180_1 may include a first portion P1 and a second portion P2.

The first portion P1 of the first lower gate contact 180_1 may extend in the second direction D2. The second portion P2 of the first lower gate contact 180_1 may extend in the first direction D1 from the first portion P1. The first lower gate contact 180_1 may be shaped similar to a rotated “L” in a planar perspective.

The first lower gate contact 180_1 may be electrically connected to the first through contact 170_1. For example, the second portion P2 of the first lower gate contact 180_1 may contact one end of the first through contact 170_1. One end of the first through contact 170_1 may be disposed on the second portion P2 of the first lower gate contact 180_1. In some embodiments, the second portion P2 of the first lower gate contact 180_1 may contact the second lower source/drain pattern 150_2. However, the present disclosure is not limited thereto.

The second lower gate contact 180_2 may include a third portion P3 and a fourth portion P4. The third portion P3 of the second lower gate contact 180_2 may extend in the second direction D2. The fourth portion P4 of the second lower gate contact 180_2 may extend in the first direction D1 from the third portion P3. The second lower gate contact 180_2 may be shaped similar to a rotated “L” in a planar perspective.

The second lower gate contact 180_2 may be electrically connected to the second through contact 170_2. For example, the fourth portion P4 of the second lower gate contact 180_2 may contact one end of the second through contact 170_2. One end of the second through contact 170_2 may be disposed on the fourth portion P4 of the second lower gate contact 180_2. In some embodiments, the fourth portion P4 of the second lower gate contact 180_2 may contact the fifth lower source/drain pattern 150_5. However, the present disclosure is not limited thereto.

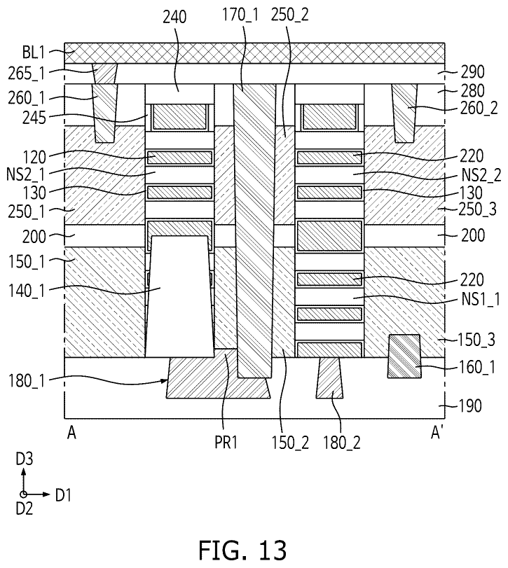

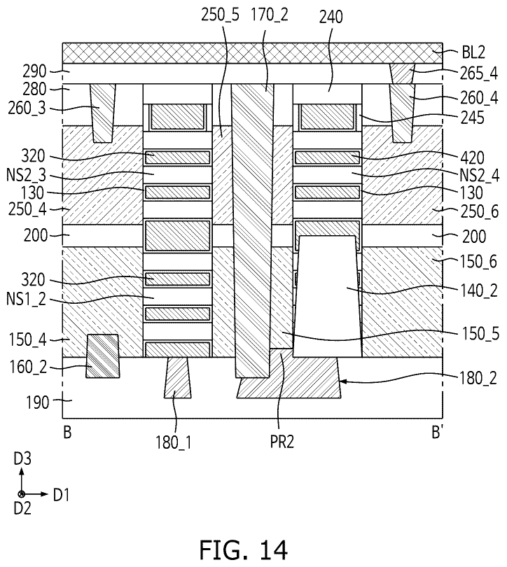

FIGS. 13 and 14 are diagrams illustrating a semiconductor device according to some embodiments of the present disclosure. For convenience of explanation, descriptions will be made focusing on components different from those described with reference to FIGS. 8-12.

Referring to FIGS. 13 and 14, in the semiconductor device according to some embodiments, the first lower gate contact 180_1 may include a first protrusion PR1, and the second lower gate contact 180_2 may include a second protrusion PR2.

The first protrusion PR1 of the first lower gate contact 180_1 may be disposed at a vertical level higher than an upper surface of the lower wiring insulating layer 190. The first protrusion PR1 of the first lower gate contact 180_1 may contact the second lower source/drain pattern 150_2. The first protrusion PR1 of the first lower gate contact 180_1 may be disposed between the first separation insulating layer 140_1 and the first through contact 170_1. The first protrusion PR1 of the first lower gate contact 180_1 may overlap the first separation insulating layer 140_1 in the first direction D1.

The second protrusion PR2 of the second lower gate contact 180_2 may be disposed at a vertical level higher than an upper surface of the lower wiring insulating layer 190. The second protrusion PR2 of the second lower gate contact 180_2 may contact the fifth lower source/drain pattern 150_5. The second protrusion PR2 of the second lower gate contact 180_2 may be disposed between the second separation insulating layer 140_2 and the second through contact 170_2. The second protrusion PR2 of the second lower gate contact 180_2 may overlap the second separation insulating layer 140_2 in the first direction D1.

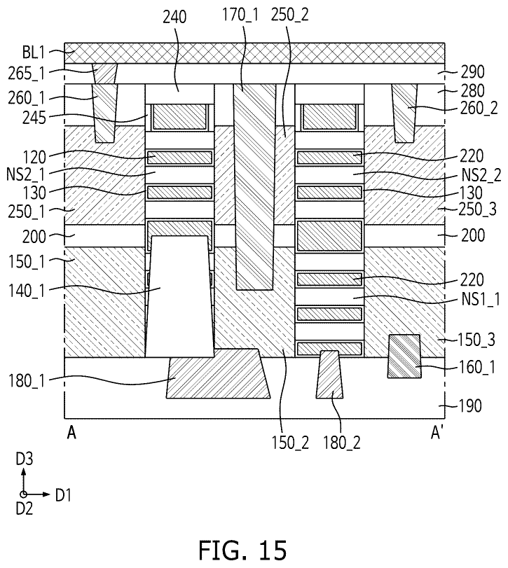

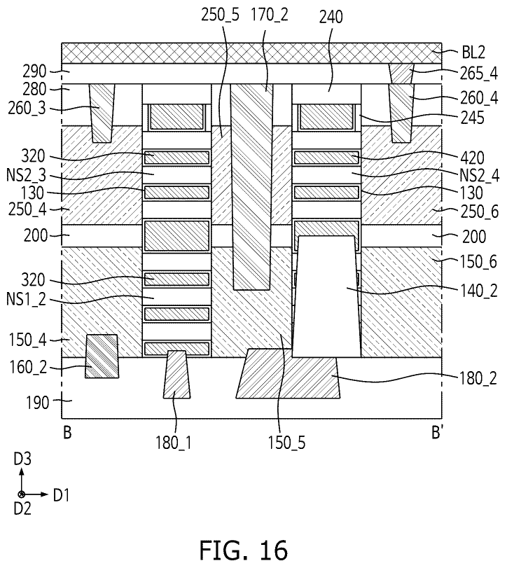

FIGS. 15 and 16 are diagrams illustrating a semiconductor device according to some embodiments of the present disclosure. For convenience of explanation, descriptions will be made focusing on components different from those described with reference to FIGS. 2-7.

Referring to FIGS. 15 and 16, in the semiconductor device according to some embodiments, the first through contact 170_1 may penetrate a portion of the second lower source/drain pattern 150_2.

The first through contact 170_1 may penetrate the middle insulating film 200, the upper and lower surfaces of the second upper source/drain pattern 250_2, and an upper surface of the second lower source/drain pattern 150_2. One end of the first through contact 170_1 may be disposed inside the second lower source/drain pattern 150_2. For example, a lower surface of the first through contact 170_1 may be disposed in the second lower source/drain pattern 150_2. The second lower source/drain pattern 150_2 may be disposed between the first through contact 170_1 and the first lower gate contact 180_1. The first through contact 170_1 may be connected to the second lower source/drain pattern 150_2 and the second upper source/drain pattern 250_2.

The first lower gate contact 180_1 may include a first portion and a second portion. The description of the first portion and the second portion of the first lower gate contact 180_1 may be similar to that described with reference to FIGS. 8-12. Hereinafter, other parts will be mainly described. The second portion of the first lower gate contact 180_1 may contact the second lower source/drain pattern 150_2. The first lower gate contact 180_1 may be connected to the second lower source/drain pattern 150_2. That is, the third gate electrode 320 may be electrically connected to the second lower source/drain pattern 150_2 through the first lower gate contact 180_1. In addition, the third gate electrode 320 may be electrically connected to the second upper source/drain pattern 250_2 through the first lower gate contact 180_1, the second lower source/drain pattern 150_2, and the first through contact 170_1.

In some embodiments, the first lower gate contact 180_1 may penetrate a lower surface of the third gate electrode 320. A portion of the first lower gate contact 180_1 may be disposed inside the third gate electrode 320. However, the present disclosure is not limited thereto. For example, the first lower gate contact 180_1 may be disposed on a lower surface of the third gate electrode 320.

The second through contact 170_2 may penetrate a portion of the fifth lower source/drain pattern 150_5. The second through contact 170_2 may penetrate the middle insulating film 200, the upper and lower surfaces of the fifth upper source/drain pattern 250_5, and an upper surface of the fifth lower source/drain pattern 150_5. One end of the second through contact 170_2 may be disposed inside the fifth lower source/drain pattern 150_5. For example, a lower surface of the second through contact 170_2 may be disposed in the fifth lower source/drain pattern 150_5. The fifth lower source/drain pattern 150_5 may be disposed between the second through contact 170_2 and the second lower gate contact 180_2. The second through contact 170_2 may be connected to the fifth lower source/drain pattern 150_5 and the fifth upper source/drain pattern 250_5.

The second lower gate contact 180_2 may include a third portion and a fourth portion. The description of the third portion and the fourth portion of the second lower gate contact 180_2 may be similar to that described with reference to FIGS. 8-12. Hereinafter, other parts will be mainly described. The fourth portion of the second lower gate contact 180_2 may contact the fifth lower source/drain pattern 150_5. The second lower gate contact 180_2 may be connected to the fifth lower source/drain pattern 150_5. That is, the second gate electrode 220 may be electrically connected to the fifth lower source/drain pattern 150_5 through the second lower gate contact 180_2. In addition, the second gate electrode 220 may be electrically connected to the fifth upper source/drain pattern 250_5 through the second lower gate contact 180_2, the fifth lower source/drain pattern 150_5, and the second through contact 170_2.

In some embodiments, the second lower gate contact 180_2 may penetrate a lower surface of the second gate electrode 220. A portion of the second lower gate contact 180_2 may be disposed inside the second gate electrode 220. However, the present disclosure is not limited thereto. For example, the second lower gate contact 180_2 may be disposed on a lower surface of the second gate electrode 220.

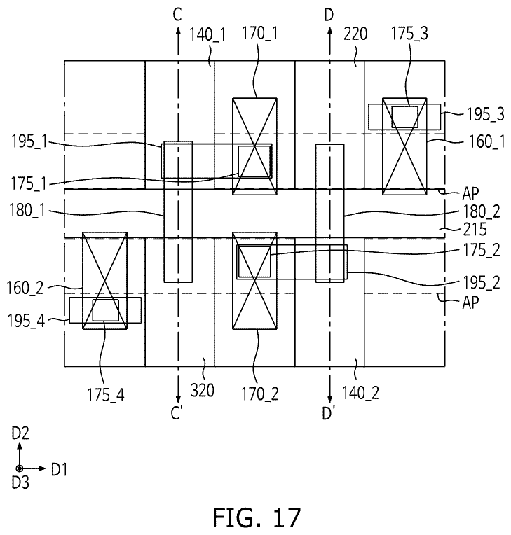

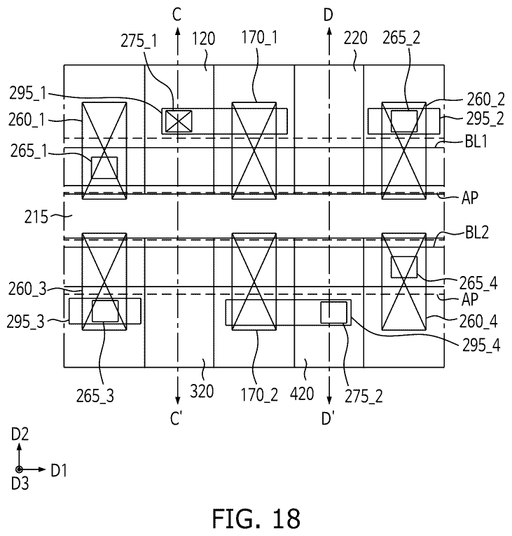

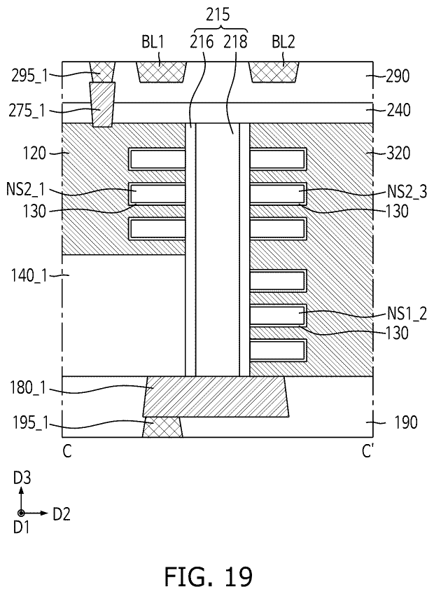

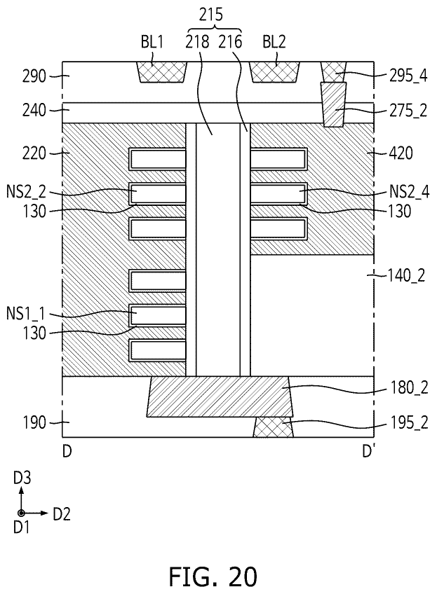

FIGS. 17 and 18 are exemplary plan views illustrating a semiconductor device according to some embodiments of the present disclosure. FIG. 19 is a cross-sectional view taken along line C-C′ of FIGS. 17 and 18. FIG. 20 is a cross-sectional view taken along line D-D′ of FIGS. 17 and 18. For convenience of explanation, descriptions will be made focusing on components different from those described with reference to FIGS. 2-7.

Referring to FIGS. 17-20, according to some embodiments of the present disclosure, the semiconductor device may include an insulating support structure 215.

The insulating support structure 215 may extend in the first direction D1 and the third direction D3. The insulating support structure 215 may be disposed on the lower wiring insulating layer 190. The insulating support structure 215 may intersect each of the first lower gate contact 180_1 and the second lower gate contact 180_2.

In some embodiments, a width of the insulating support structure 215 in the second direction D2 may be uniform. However, the present disclosure is not limited thereto.

The insulating support structure 215 may be disposed between the plurality of first upper sheet patterns NS2_1 and the plurality of third upper sheet patterns NS2_3. The insulating support structure 215 may be disposed between the first separation insulating layer 140_1 and the plurality of second lower sheet patterns NS1_2. The insulating support structure 215 may be disposed between the plurality of second upper sheet patterns NS2_2 and the plurality of fourth upper sheet patterns NS2_4. The insulating support structure 215 may be disposed between the plurality of first lower sheet patterns NS1_1 and the second separation insulating layer 140_2.

In some embodiments, the insulating support structure 215 may contact each side surface of the upper sheet patterns NS2_1, NS2_2, NS2_3, NS2_4 and the lower sheet patterns NS1_1, NS1_2. For example, the insulating support structure 215 may contact a side surface of the first upper sheet pattern NS2_1. The first gate electrode 120 may surround three surfaces of the first upper sheet pattern NS2_1. A gate insulating film 130 and the first gate electrode 120 may not be disposed between the first upper sheet pattern NS2_1 and the insulating support structure 215. Because the first gate electrode 120 is not disposed between the insulating support structure 215 and the first upper sheet pattern NS2_1, the distance between the first upper sheet pattern NS2_1 and the third upper sheet pattern NS2_3 may be decreased. Accordingly, the degree of integration of the semiconductor device may be improved.

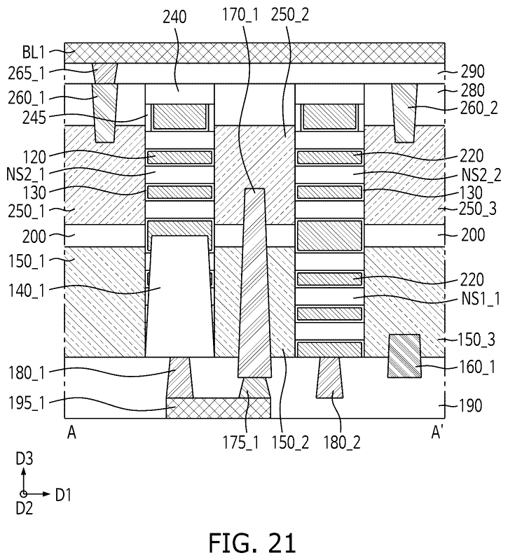

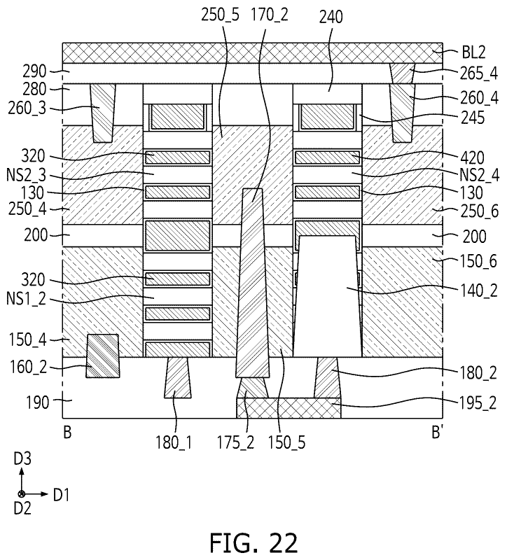

FIGS. 21 and 22 are diagrams illustrating a semiconductor device according to some embodiments of the present disclosure. For convenience of explanation, descriptions will be made focusing on components different from those described with reference to FIGS. 2-7.

Referring to FIGS. 21 and 22, in the semiconductor device according to some embodiments, the first through contact 170_1 may penetrate a portion of the second upper source/drain pattern 250_2.

The first through contact 170_1 may penetrate the middle insulating film 200, upper and lower surfaces of the second lower source/drain pattern 150_2, and a lower surface of the second upper source/drain pattern 250_2. One end of the first through contact 170_1 may be disposed inside the second upper source/drain pattern 250_2. For example, an upper surface of the first through contact 170_1 may be disposed in the second upper source/drain pattern 250_2. The first through contact 170_1 may be connected to the second lower source/drain pattern 150_2 and the second upper source/drain pattern 250_2.

A width of the first through contact 170_1 in the first direction D1 may not be uniform. For example, the width of the first through contact 170_1 in the first direction D1 may increase as it becomes farther from the first bit line BL1. The first through contact 170_1 may have an inclined side surface.

The second through contact 170_2 may penetrate a portion of the fifth upper source/drain pattern 250_5. The second through contact 170_2 may penetrate the middle insulating film 200, upper and lower surfaces of the fifth lower source/drain pattern 150_5, and a lower surface of the fifth upper source/drain pattern 250_5. One end of the second through contact 170_2 may be disposed inside the fifth upper source/drain pattern 250_5. For example, an upper surface of the second through contact 170_2 may be disposed in the fifth upper source/drain pattern 250_5. The second through contact 170_2 may be connected to the fifth lower source/drain pattern 150_5 and the fifth upper source/drain pattern 250_5.

A width of the second through contact 170_2 in the first direction D1 may not be uniform. For example, the width of the second through contact 170_2 in the first direction D1 may increase as it becomes farther from the second bit line BL2. The second through contact 170_2 may have an inclined side surface.

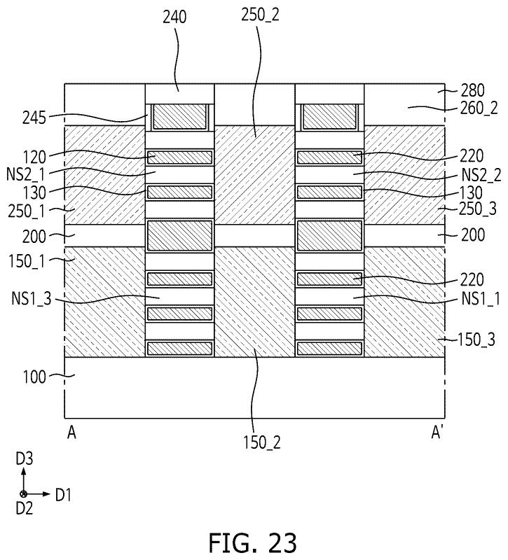

FIGS. 23-34 are diagrams illustrating a method of manufacturing a semiconductor device according to some embodiments of the present disclosure. FIGS. 23, 25, 27, 29, 31, and 33 correspond to cross-sectional views taken along line A-A′ of FIGS. 2 and 3, and FIGS. 24, 26, 28, 30, 32, and 34 correspond to cross-sectional views taken along line B-B′ of FIGS. 2 and 3. For convenience of explanation, configurations identical to those described with reference to FIGS. 2-7 are omitted or briefly described.

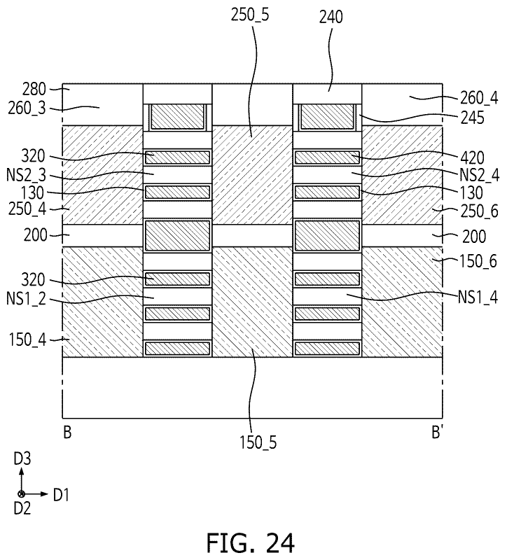

Referring to FIGS. 23 and 24, a plurality of first to fourth lower sheet patterns NS1_1, NS1_2, NS1_3, NS1_4, a plurality of first to fourth upper sheet patterns NS2_1, NS2_2, NS2_3, NS2_4, first to fourth gate electrodes 120, 220, 320, 420, first to sixth lower source/drain patterns 150_1, 150_2, 150_3, 150_4, 150_5, 150_6, and first to sixth upper source/drain patterns 250_1, 250_2, 250_3, 250_4, 250_5, 250_6 may be formed on a substrate 100.

The substrate 100 may be bulk silicon or SOI (silicon-on-insulator). Alternatively, the substrate 100 may include silicon germanium (SiGe), SGOI (silicon germanium on insulator), indium antimonide, lead tellurium compounds, indium arsenide, indium phosphide, gallium arsenide, or gallium antimonide, without being limited thereto.

The plurality of first to fourth lower sheet patterns NS1_1, NS1_2, NS1_3, NS1_4 and the plurality of first to fourth upper sheet patterns NS2_1, NS2_2, NS2_3, NS2_4 may be formed on the substrate 100. The plurality of third lower sheet patterns NS1_3 may be spaced apart in the first direction D1 from the plurality of first lower sheet patterns NS1_1. The plurality of fourth lower sheet patterns NS1_4 may be spaced apart in the first direction D1 from the plurality of second lower sheet patterns NS1_2.

Subsequently, the first to sixth lower source/drain patterns 150_1, 150_2, 150_3, 150_4, 150_5, 150_6 may be formed on the substrate 100. A middle insulating film 200 may be formed on the first to sixth lower source/drain patterns 150_1, 150_2, 150_3, 150_4, 150_5, 150_6. The first to sixth upper source/drain patterns 250_1, 250_2, 250_3, 250_4, 250_5, 250_6 may be formed on the middle insulating film 200. An upper interlayer insulating film 280 may be formed on upper surfaces of the first to sixth upper source/drain patterns 250_1, 250_2, 250_3, 250_4, 250_5, 250_6.

Then, the first to fourth gate electrodes 120, 220, 320, 420 may be formed. The first gate electrode 120 may surround the plurality of first upper sheet patterns NS1_1 and the plurality of third lower sheet patterns NS1_3. The fourth gate electrode 420 may surround the plurality of fourth upper sheet patterns NS2_4 and the plurality of fourth lower sheet patterns NS1_4. A gate capping pattern 240 may be formed on the upper surfaces of the first to fourth gate electrodes 120, 220, 320, 420.

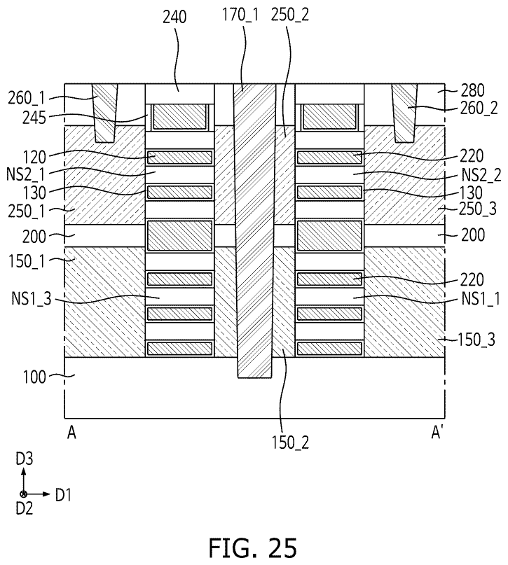

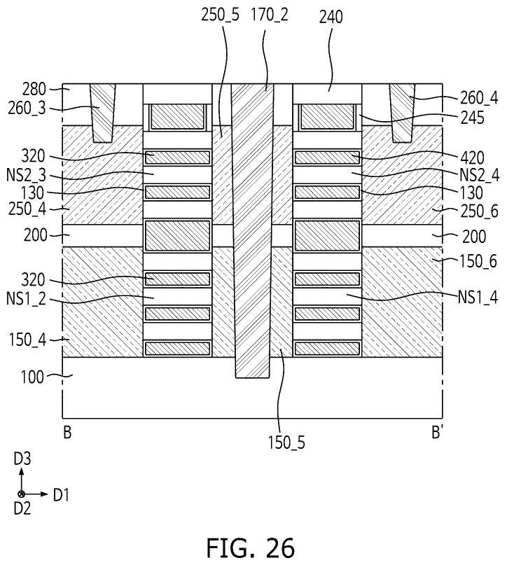

Referring to FIGS. 25 and 26, the first to fourth upper source/drain contacts 260_1, 260_2, 260_3, 260_4 and the first and second through contacts 170_1, 170_2 may be formed.

Specifically, the first through contact 170_1 and the second through contact 170_2 may be formed first. The first through contact 170_1 may penetrate the upper interlayer insulating film 280, the second upper source/drain pattern 250_2, the middle insulating film 200, and the second lower source/drain pattern 150_2. The second through contact 170_2 may penetrate the upper interlayer insulating film 280, the fifth upper source/drain pattern 250_5, the middle insulating film 200, and the fifth lower source/drain pattern 150_5. However, the present disclosure is not limited thereto. For example, the shapes of the first through contact 170_1 and the second through contact 170_2 may be the same as those shown in FIGS. 15 and 16.

Subsequently, the first to fourth upper source/drain contacts 260_1, 260_2, 260_3, 260_4 may be formed. The description of the first to fourth upper source/drain contacts 260_1, 260_2, 260_3, 260_4 may be identical to that described above.

Although it was described that the first and second through contacts 170_1, 170_2 are formed first, followed by formation of the first to fourth upper source/drain contacts 260_1, 260_2, 260_3, 260_4, the present disclosure is not limited thereto. For example, the first to fourth upper source/drain contacts 260_1, 260_2, 260_3, 260_4 may be formed first, followed by formation of the first and second through contacts 170_1, 170_2.

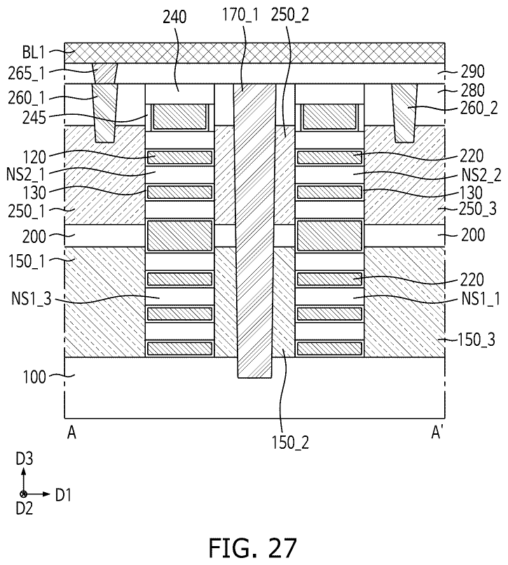

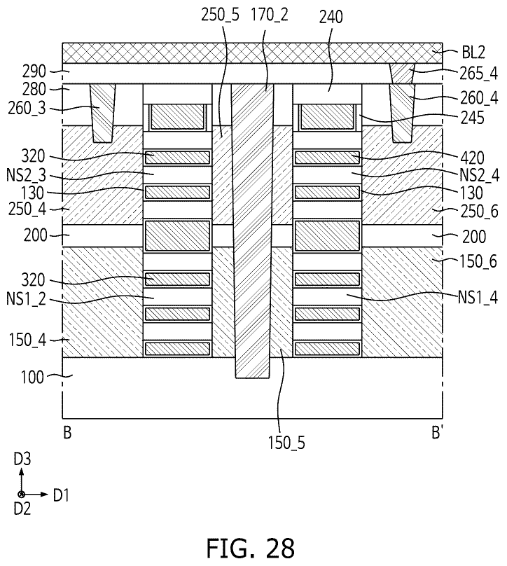

Referring to FIGS. 27 and 28, the first bit line BL1 and the second bit line BL2 may be formed.

Specifically, a first upper via 265_1 may be formed on the first upper source/drain contact 260_1, and the first bit line BL1 may be formed on the first upper via 265_1. In addition, a fourth upper via 265_4 may be formed on the fourth upper source/drain contact 260_4, and the second bit line BL2 may be formed on the fourth upper via 265_4. In some embodiments, the first to fourth upper line wiring 295_1, 295_2, 295_3, 295_4 described with reference to FIGS. 2-7 may be formed by the same process as the first and second bit lines BL1, BL2.

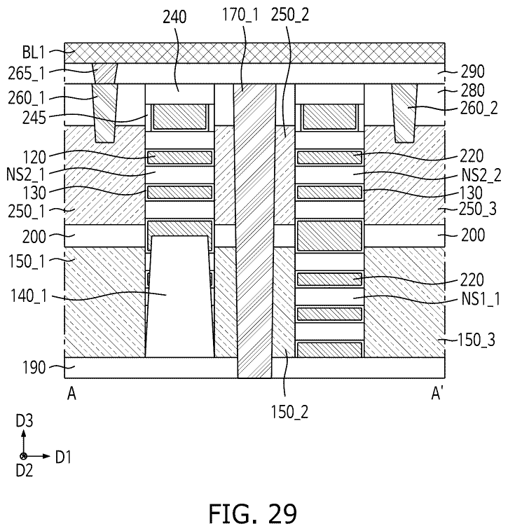

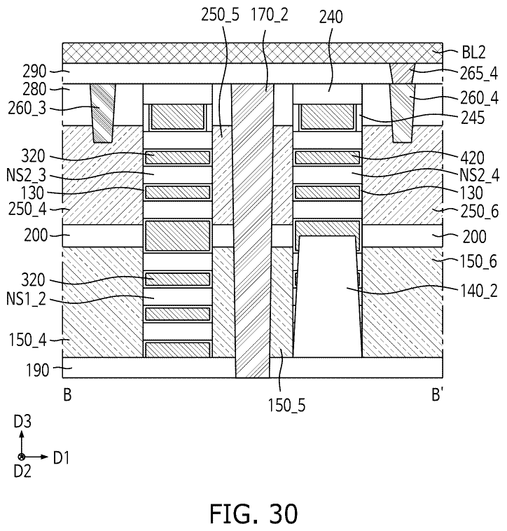

Referring to FIGS. 29 and 30, the first separation insulating layer 140_1 and the second separation insulating layer 140_2 may be formed.

Specifically, the substrate (100 in FIG. 27) is removed, and lower surfaces of the first gate electrode 120 and the fourth gate electrode 420 are exposed. Then, a portion of the first gate electrode 120 and the plurality of third lower sheet patterns (NS1_3 in FIG. 27) is removed, and the first separation insulating layer 140_1 is formed. Likewise, a portion of the fourth gate electrode 420 and the plurality of fourth lower sheet patterns (NS1_4 in FIG. 27) is removed, and the second separation insulating layer 140_2 is formed. Then, the lower wiring insulating layer 190 may be formed.

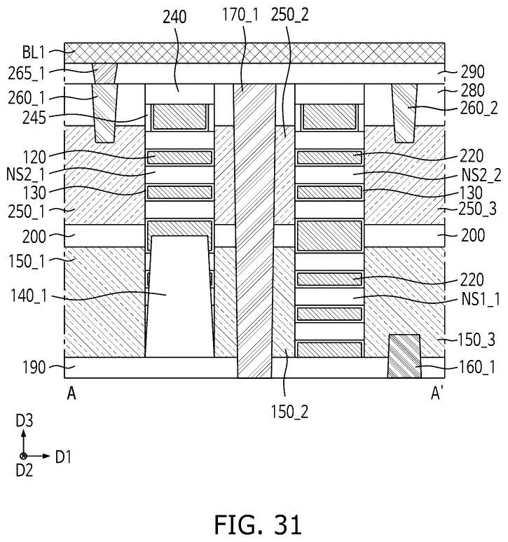

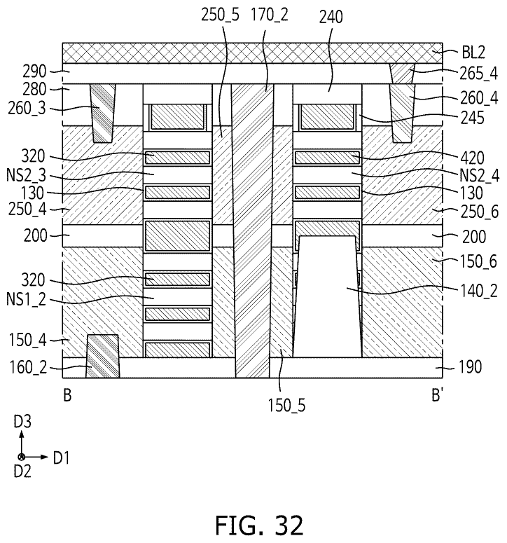

Referring to FIGS. 31 and 32, the first lower source/drain contact 160_1 and the second lower source/drain contact 160_2 may be formed.

The first lower source/drain contact 160_1 may be formed on the third lower source/drain pattern 150_3. The first lower source/drain contact 160_1 may penetrate a lower surface of the third lower source/drain pattern 150_3. The second lower source/drain contact 160_2 may be formed on the fourth lower source/drain pattern 150_4. The second lower source/drain contact 160_2 may penetrate a lower surface of the fourth lower source/drain pattern 150_4.

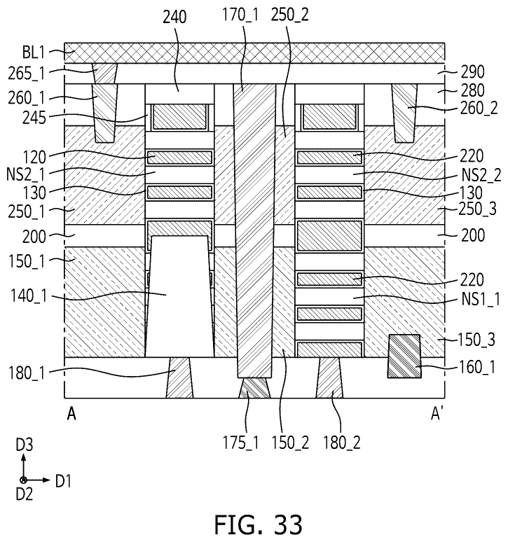

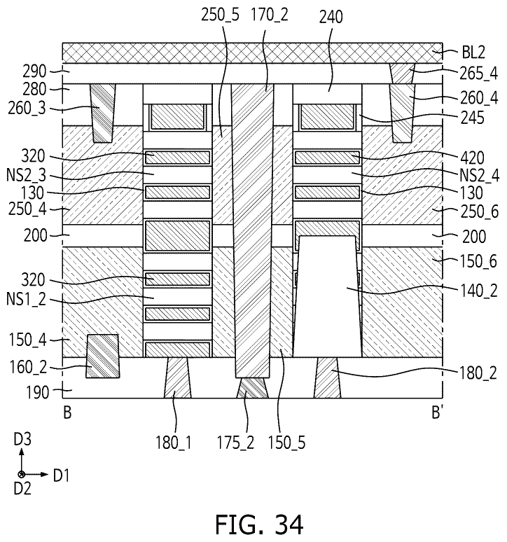

Referring to FIGS. 33 and 34, the first and second lower gate contacts 180_1, 180_2 and the first and second lower vias 175_1, 175_2 may be formed.

The first lower gate contact 180_1 may extend in the second direction D2. The first lower gate contact 180_1 may be disposed on a lower surface of the first separation insulating layer 140_1 and a lower surface of the third gate electrode 320. The second lower gate contact 180_2 may extend in the second direction D2. The second lower gate contact 180_2 may be disposed on a lower surface of the second separation insulating layer 140_2 and a lower surface of the second gate electrode 220.

The first lower via 175_1 may be formed on a lower surface of the first through contact 170_1. The second lower via 175_2 may be formed on a lower surface of the second through contact 170_2. Although it was described that the first and second lower gate contacts 180_1, 180_2 are formed first and then the first and second lower vias 175_1, 175_2 are formed, the present disclosure is not limited thereto. For example, the first and second lower vias 175_1, 175_2 may be formed first, followed by formation of the first and second lower gate contacts 180_1, 180_2.

In some embodiments, the first lower via 175_1 and the second lower via 175_2 may be omitted, and each of the first lower gate contact 180_1 and the second lower gate contact 180_2 may include a portion extending in the first direction D1. For example, the shape of each of the first lower gate contact 180_1 and the second lower gate contact 180_2 may be the same as those shown in FIGS. 8-12. In addition, the shape of each of the first lower gate contact 180_1 and the second lower gate contact 180_2 may be the same as shown in FIGS. 13 and 14 or FIGS. 15 and 16.

Finally, referring to FIGS. 4 and 5, the first lower line wiring 195_1 and the second lower line wiring 195_2 may be formed. In some embodiments, when the first lower line wiring 195_1 and the second lower line wiring 195_2 are formed, the third lower line wiring 195_3 of FIG. 2 and the fourth lower line wiring 195_4 of FIG. 3 may be formed together.

Although certain embodiments of the present disclosure have been described with reference to the accompanying drawings, those of ordinary skill in the art to which the present disclosure pertains will understand that the present disclosure may be implemented in other specific forms without changing its technical idea or essential features. Therefore, it should be understood that the embodiments described above are illustrative and non-limiting in all respects.

What is claimed is:

1. A semiconductor device comprising:
a plurality of upper sheet patterns spaced apart from one another in a first direction on a first separation insulating layer;
a first gate electrode surrounding the plurality of upper sheet patterns and extending in a second direction intersecting the first direction;
a second gate electrode spaced apart from the first gate electrode in the second direction and extending in the second direction;
a lower source/drain pattern disposed on one side of the first separation insulating layer;
a first upper source/drain pattern disposed on one side of the plurality of upper sheet patterns and spaced apart from the lower source/drain pattern in the first direction;
a first through contact extending in the first direction and penetrating at least a portion of the first upper source/drain pattern and at least a portion of the lower source/drain pattern; and
a first lower gate contact disposed on a lower surface of the second gate electrode and extending in the second direction,
wherein the first lower gate contact is electrically connected to the first through contact.

2. The semiconductor device according to claim 1, further comprising:
a lower via disposed on a lower surface of the first through contact; and
a lower line wiring disposed on a lower surface of the lower via and extending in a third direction intersecting each of the first direction and the second direction,
wherein the lower line wiring is disposed on a lower surface of the first lower gate contact.

3. The semiconductor device according to claim 1, wherein a portion of the first lower gate contact overlaps the first separation insulating layer in the first direction.

4. The semiconductor device according to claim 1, further comprising:
a third gate electrode spaced apart from the first gate electrode in a third direction intersecting each of the first direction and the second direction;
a second lower gate contact disposed on a lower surface of the third gate electrode and extending in the second direction; and
a second through contact spaced apart from the first through contact in the second direction,
wherein the second lower gate contact is electrically connected to the second through contact.

5. The semiconductor device according to claim 4, further comprising a second separation insulating layer spaced apart from the second gate electrode in the third direction,
wherein a lower surface of the first separation insulating layer is disposed at a same vertical level as a lower surface of the second separation insulating layer, and
wherein a portion of the second lower gate contact overlaps the second separation insulating layer in the first direction.

6. The semiconductor device according to claim 1, further comprising:
a second upper source/drain pattern disposed on another side of the plurality of upper sheet patterns; and
a bit line extending in a third direction intersecting each of the first direction and the second direction and electrically connected to the second upper source/drain pattern.

7. The semiconductor device according to claim 6, wherein a width of the first through contact in the third direction decreases as the first through contact becomes farther from the bit line.

8. The semiconductor device according to claim 1, wherein the first lower gate contact comprises a first portion extending in the second direction and a second portion extending in a third direction intersecting each of the first direction and the second direction from the first portion,
wherein the second portion is disposed on a lower surface of the first through contact.

9. The semiconductor device according to claim 8, wherein the second portion is in contact with the lower source/drain pattern.

10. The semiconductor device according to claim 1, wherein the first lower gate contact comprises a first portion extending in the second direction and a second portion extending in a third direction intersecting each of the first direction and the second direction from the first portion,
wherein the second portion is in contact with the lower source/drain pattern, and
wherein one end of the first through contact is disposed in the lower source/drain pattern.

11. The semiconductor device according to claim 1, wherein the first through contact penetrates each of an upper surface of the first upper source/drain pattern and a lower surface of the lower source/drain pattern.

12. The semiconductor device according to claim 1, wherein the first separation insulating layer is disposed between the first gate electrode and the first lower gate contact.

13. The semiconductor device according to claim 1, further comprising a gate separation structure disposed between the first gate electrode and the second gate electrode.

14. A semiconductor device comprising:
a plurality of upper sheet patterns spaced apart from one another in a first direction on a separation insulating layer;
a first gate electrode surrounding the plurality of upper sheet patterns and extending in a second direction intersecting the first direction;
a first upper source/drain pattern and a second upper source/drain pattern disposed on both sides of the plurality of upper sheet patterns;
a first lower source/drain pattern disposed on one side of the separation insulating layer;
a through contact extending in the first direction and penetrating at least a portion of each of the second upper source/drain pattern and the first lower source/drain pattern;
a third upper source/drain pattern spaced apart from the second upper source/drain pattern in a third direction intersecting each of the first direction and the second direction;
a second lower source/drain pattern spaced apart from the first lower source/drain pattern in the third direction;
a second gate electrode disposed between the first lower source/drain pattern and the second lower source/drain pattern and between the second upper source/drain pattern and the third upper source/drain pattern;
a third gate electrode spaced apart from the first gate electrode in the second direction;
a first upper line wiring electrically connected to the third upper source/drain pattern;
a first lower line wiring electrically connected to the second lower source/drain pattern; and
a lower gate contact disposed on a lower surface of the third gate electrode, extending in the second direction, and electrically connected to the through contact.

15. The semiconductor device according to claim 14, further comprising:
an upper source/drain contact disposed on the first upper source/drain pattern; and
a bit line connected to the upper source/drain contact,
wherein the bit line and the first upper line wiring are disposed at a same vertical level.

16. The semiconductor device according to claim 15, further comprising:
an upper gate contact disposed on the first gate electrode; and
a second upper line wiring disposed on the upper gate contact,
wherein the first upper line wiring is disposed at a same vertical level as the second upper line wiring.

17. The semiconductor device according to claim 14, further comprising:
a lower via disposed on a lower surface of the through contact; and
a second lower line wiring disposed on a lower surface of the lower via and electrically connecting the lower via and the lower gate contact.

18. The semiconductor device according to claim 17, wherein the first lower line wiring and the second lower line wiring are disposed at a same vertical level.

19. The semiconductor device according to claim 14, wherein the lower gate contact comprises a first portion extending in the second direction and a second portion extending in the third direction from the first portion,
wherein the second portion contacts a lower surface of the through contact.

20. A semiconductor device comprising:
a plurality of upper sheet patterns spaced apart from one another in a first direction on a separation insulating layer;
a first gate electrode surrounding the plurality of upper sheet patterns and extending in a second direction intersecting the first direction;
a first upper source/drain pattern and a second upper source/drain pattern respectively disposed on both sides of the plurality of upper sheet patterns;
a first lower source/drain pattern disposed on one side of the separation insulating layer;
a through contact extending in the first direction and penetrating each of the second upper source/drain pattern and the first lower source/drain pattern;
a third upper source/drain pattern spaced apart from the second upper source/drain pattern in a third direction intersecting each of the first direction and the second direction;
a second lower source/drain pattern spaced apart from the first lower source/drain pattern in the third direction;
a second gate electrode disposed between the first lower source/drain pattern and the second lower source/drain pattern and between the second upper source/drain pattern and the third upper source/drain pattern;
a third gate electrode spaced apart from the first gate electrode in the second direction;
a lower gate contact disposed on a lower surface of the third gate electrode, electrically connected to the through contact, and extending in the second direction;
a lower via disposed on a lower surface of the through contact;
a first lower line wiring disposed on a lower surface of the lower via and connecting the lower via and the lower gate contact;
a second lower line wiring electrically connected to the second lower source/drain pattern;
a bit line electrically connected to the first upper source/drain pattern;
a first upper line wiring electrically connected to the third upper source/drain pattern; and
a second upper line wiring electrically connected to the first gate electrode,
wherein the first lower line wiring and the second lower line wiring are disposed at a same vertical level, and
wherein the bit line, the first upper line wiring, and the second upper line wiring are disposed at a same vertical level.
